(19) United States
(12) Patent Application Publication
(10) Pub. No.: US 2013/0095428 A1
(43) Pub. Date: Apr. 18, 2013

(54) RADIATION-SENSITIVE RESIN COMPOSITION

(71) Applicant: JSR Corporation, Tokyo (JP)

(72) Inventors: Kazuki KASAHARA, Tokyo (JP); Kazuo NAKAHARA, Tokyo (JP); Hiromu MIYATA, Tokyo (JP); Tomoki NAGAI, Tokyo (JP)

(73) Assignee: JSR CORPORATION, Tokyo (JP)

(21) Appl. No.: 13/653,468

(22) Filed: Oct. 17, 2012

(30) Foreign Application Priority Data
Oct. 17, 2011 (JP) 2011-228289

(51) Int. Cl. G03F 7/027

(52) U.S. Cl. 430/285.1; 430/281.1

(57) ABSTRACT

A radiation-sensitive resin composition includes a compound represented by a following formula (1) and a base polymer. In the formula (1), R¹ represents a monovalent cyclic organic group having a cyclic ester structure or a cyclic ketone structure; R² represents a single bond or —CH₂—; X is —O—*, —COO—*, —O—CO—O—* or —SO2-O—*, wherein * denotes a binding site to R³; R³ represents a bivalent chain hydrocarbon group having 1 to 5 carbon atoms; and M⁺ is a monovalent cation. The base polymer has a structural unit derived from (meth)acrylate that includes a lactone skeleton, a structural unit derived from (meth)acrylate that includes a cyclic carbonate skeleton, a structural unit derived from (meth)acrylate that includes a sultone skeleton, a structural unit derived from (meth)acrylate that includes a polar group, or a combination thereof.

R¹—R²—X—R³—CHF—CF₂—SO₃⁻M⁺ (1)

### CROSS-REFERENCE TO RELATED APPLICATIONS

The present application claims priority under 35 U.S.C. §119 to Japanese Patent Application No. 2011-228289, filed Oct. 17, 2011. The contents of this application are incorporated herein by reference in their entirety.

### BACKGROUND OF THE INVENTION

1. Field of the Invention

The present invention relates to a radiation-sensitive resin composition.

2. Discussion of the Background

In the field of microfabrication, etc., typified by manufacturing of integrated circuit elements, in order to achieve higher integrity, lithography techniques have been recently required that enable microfabrication at a level of no greater than about 100 nm using a far ultraviolet ray such as a KrF excimer laser beam, an ArF excimer laser beam, an F₂ excimer laser beam or an EUV (extreme ultraviolet) ray, an X-ray such as a synchrotron radioactive ray, a charged particle ray such as an electron beam, or the like. As radiation-sensitive resin compositions suited for such a radioactive ray, a number of chemically amplified radiation-sensitive resin compositions have been proposed which contain a component having an acid-dissociable group and an acid generating agent which is a component that generates an acid by irradiation with a radioactive ray, and utilizes a chemical amplification effect between these components. Such a radiation-sensitive resin composition which has been known contains, for example, a polymer derived from a monomer including a norbornane ring derivative (see Japanese Unexamined Patent Application, Publication Nos. 2002-201232 and 2002-145955). Moreover, a radiation-sensitive resin composition containing in addition to a component having an acid-dissociable group and an acid generating agent, a photoactive compound further added in order to improve sensitivity and resolution has been also known (see Japanese Unexamined Patent Application, Publication No. 2002-363123).

Under such circumstances, demands for higher integrity in the field of semiconductors, etc., lead to a requirement for resist coating films having more balanced lithography performances. Particularly, a resist coating film that exhibits favorable resistance to pattern collapse after development, LWR (Line Width Roughness) and MEEF (Mask Error Enhancement Factor), which are well balanced has been strongly demanded. Additionally, a resist coating film not accompanied by development defects also in the case in which a liquid immersion lithography process is used has been particularly demanded.

### SUMMARY OF THE INVENTION

According to one aspect of the present invention, a radiation-sensitive resin composition includes a compound represented by a following formula (1) and a base polymer. In the formula (1), R¹ represents a monovalent cyclic organic group having a cyclic ester structure or a cyclic ketone structure; R² represents a single bond or —CH₂—; X is —O—*, —COO—*, —O—CO—O—* or —SO2-O—*, wherein * denotes a binding site to R³; R³ represents a bivalent chain hydrocarbon group having 1 to 5 carbon atoms; and M⁺ is a monovalent cation. The base polymer has a structural unit derived from (meth)acrylate that includes a lactone skeleton, a structural unit derived from (meth)acrylate that includes a cyclic carbonate skeleton, a structural unit derived from (meth)acrylate that includes a sultone skeleton, a structural unit derived from (meth)acrylate that includes a polar group, or a combination thereof.

R¹—R²—X—R³—CHF—CF₂—SO₃⁻M⁺ (1)

### DESCRIPTION OF EMBODIMENTS

A radiation-sensitive resin composition of the embodiment of the present invention contains a polymer that serves as a base having a specific structural unit (hereinafter, may be referred to as “base polymer”), and a compound having a specific structure that serves as an acid generating agent.

More specifically, a radiation-sensitive resin composition according to one aspect of an embodiment of the present invention contains:

(A) a compound represented by the following formula (1) (hereinafter, may be also referred to as “compound (A)”); and

(B) a base polymer (hereinafter, may be also referred to as “polymer (B)”) having at least one structural unit (hereinafter, may be also referred to as “structural unit (1)”) selected from the group consisting of a structural unit derived from (meth)acrylate that includes a lactone skeleton (hereinafter, may be also referred to as “structural unit (1-1)”), a structural unit derived from (meth)acrylate that includes a cyclic carbonate skeleton (hereinafter, may be also referred to as “structural unit (1-2)”), a structural unit derived from (meth)acrylate that includes a sultone skeleton (hereinafter, may be also referred to as “structural unit (1-3)”), and a structural unit derived from (meth)acrylate that includes a polar group (hereinafter, may be also referred to as “structural unit (1-4)”).

R¹—R²—X—R³—CHF—CF₂—SO₃⁻M⁺ (1)

In the formula (1), R¹ represents a monovalent cyclic organic group having a cyclic ester structure or a cyclic ketone structure; R² represents a single bond or —CH₂—; X is —O—*, —COO—*, —O—CO—O—* or —SO2-O—*, wherein, * denotes a binding site to R³; R³ represents a bivalent chain hydrocarbon group having 1 to 5 carbon atoms; and M⁺ is a monovalent cation.

It is preferred that the radiation-sensitive resin composition further contains (C) a fluorine-containing polymer (hereinafter, may be also referred to as “polymer (C)”).

In addition, according to the radiation-sensitive resin composition, R¹ in the above formula (1) is preferably a group represented by a following formula (a1), a group represented by a following formula (a2), or a group represented by a following formula (a3).

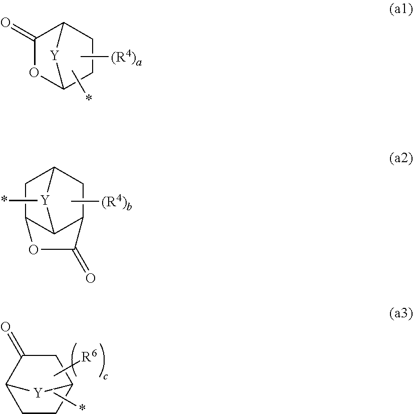

In the formulae (a1) to (a3), Y is each independently —CH₂—, —C(CH₃)₂— or —O—; R⁴, R⁵ and R⁶ each independently represent an alkyl group having 1 to 5 carbon atoms, a cyano group or a hydroxyl group; a, b and c are each independently an integer of 0 to 5; and * denotes a binding site to R².

Furthermore, in the radiation-sensitive resin composition, M⁺ in the above formula (1) is preferably a sulfonium cation or an iodonium cation, and more preferably a cation represented by the following formula (b).

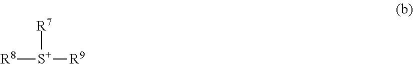

In the formula (b), R⁷, R⁸ and R⁹ each independently represent a substituted or unsubstituted linear or branched alkyl group, alkenyl group or oxoalkyl group having 1 to 10 carbon atoms, or a substituted or unsubstituted aryl group, aralkyl group or aryloxoalkyl group having 6 to 18 carbon atoms, or any two or more of R⁷, R⁸ and R⁹ optionally taken together represent a ring together with the sulfur atom present in the formula.

It is preferred that the polymer (B) further has a structural unit represented by the following formula (2) (hereinafter, may be also referred to as “structural unit (2)”) in the radiation-sensitive resin composition.

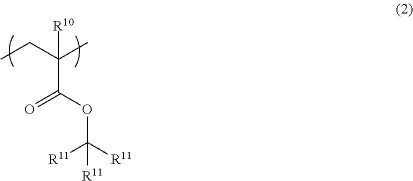

In the formula (2), R¹⁰ represents a hydrogen atom or a methyl group; R¹¹ each independently represents a linear or branched alkyl group having 1 to 4 carbon atoms, or an alicyclic hydrocarbon group having 4 to 20 carbon atoms, wherein, two R¹¹s optionally taken together represent an alicyclic hydrocarbon group having 4 to 20 carbon atoms together with the carbon atom to which the R¹¹s bond.

Furthermore, according to the radiation-sensitive resin composition, the polymer (B) preferably has a structural unit derived from (meth)acrylate that includes a polar group, and the polar group is preferably a hydroxyl group.

The radiation-sensitive resin composition of the embodiment of the present invention is capable of forming a chemically amplified resist coating film that is favorable in LWR and MEEF, which are well balanced, and accompanied by fewer development defects.

Hereinafter, embodiments of the radiation-sensitive resin composition of the present invention will be explained. However, it should be construed that the present invention is not limited to the following embodiments, and any appropriate alterations, modifications and the like of the following embodiments made without departing from the spirit of the present invention, based on common knowledges that persons skilled in the art have may fall within the scope of the present invention.

The radiation-sensitive resin composition of the embodiment of the present invention contains (A) a compound and (B) a polymer. The radiation-sensitive resin composition may contain (C) a polymer, (D) an acid diffusion control agent and (E) a lactone compound as suitable components, and further may contain other optional component(s).

### [(A) Compound]

The compound (A) is represented by the above formula (1). The compound (A) generates a compound (acid) represented by the formula of: R¹—R²—X—R³—CHF—CF₂—SO₃H by the irradiation with a radioactive ray. Due to including a cyclic ester structure or a cyclic ketone structure in the compound (A), the obtained radiation-sensitive resin composition can inhibit development defects.

In the above formula (1), R¹ represents a monovalent cyclic organic group having a cyclic ester structure or a cyclic ketone structure; R² represents a single bond or —CH₂—; X is —O—*, —COO—*, —O—CO—O—* or —SO2-O—*, wherein * denotes a binding site to R³; R³ represents a bivalent chain hydrocarbon group having 1 to 5 carbon atoms, which may be linear or branched; and M⁺ is a monovalent cation.

Examples of the bivalent chain hydrocarbon group having 1 to 5 carbon atoms represented by the R³ include a methylene group, an ethanediyl group, a propanediyl group, a 1-methylethanediyl group, a butanediyl group, a 1-methylpropanediyl group, a 2-methylpropanediyl group, a 1-ethylethanediyl group, a pentanediyl group, 1-methylbutanediyl group, 2-methylbutanediyl group, 1-ethylpropanediyl group, 2-ethylpropanediyl group, and the like. Of these, linear hydrocarbon groups are preferred, linear hydrocarbon groups having 1 to 3 carbon atoms are more preferred, and a methylene group is still more preferred.

The R¹ is not particularly limited as long as it is a monovalent organic group having a cyclic ester structure or a cyclic ketone structure, and is preferably a group represented by a following formula (a1), a group represented by a following formula (a2), or a group represented by a following formula (a3).

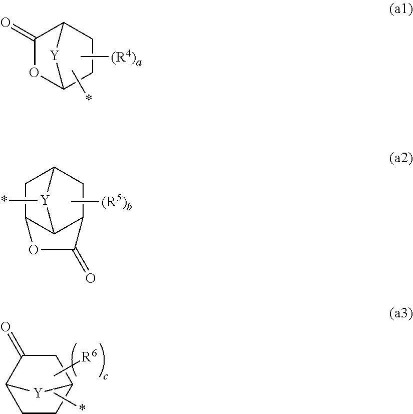

In the above formulae (a1) to (a3), Y is each independently —CH₂—, —C(CH₃)₂— or —O—; R⁴, R⁵ and R⁶ each independently represent an alkyl group having 1 to 5 carbon atoms, a cyano group or a hydroxyl group; a, b and c are each independently an integer of 0 to 5; and * denotes a binding site to R². Examples of the alkyl group having 1 to 5 carbon atoms represented by the R⁴, R⁵ and R⁶ include a methyl group, an ethyl group, a 1-propyl group, a 2-propyl group, a 1-butyl group, a 2-butyl group, a 2-(2-methylpropyl) group, a 1-pentyl group, a 2-pentyl group, a 3-pentyl group, a 1-(2-methylbutyl) group, a 1-(3-methylbutyl) group, a 2-(2-methylbutyl) group, a 2-(3-methylbutyl) group, a neopentyl group, and the like.

The group represented by the above formula (a1) is exemplified by groups represented by the following formula (a1-1). The group represented by the above formula (a2) is exemplified by groups represented by the following formulae (a2-1) to (a2-2). The group represented by the above formula (a3) is exemplified by groups represented by the following formula (a3-1), and the like. Wherein, * denotes a binding site to R².

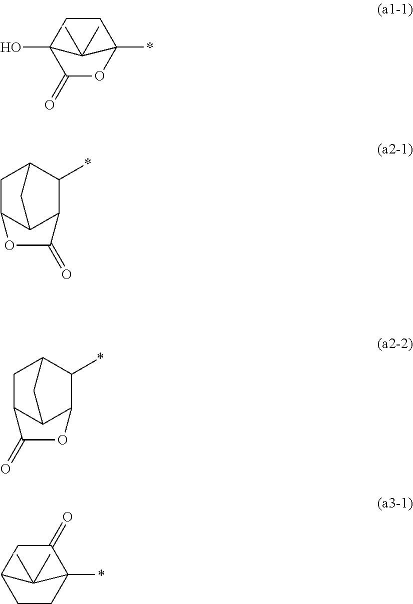 [SMILES: *C12CCC(O)(C(=O)O1)C2(C)C ; *C1C2CC3OC(=O)C1C3C2 ; *C1C2CC3C(=O)OC1C3C2 ; *C12CCC(CC1=O)C2(C)C]

A preferable anion represented by the formula of: R¹—R²—X—R³—CHF—CF₂—SO₃⁻ is exemplified by anions represented by the following formulae.

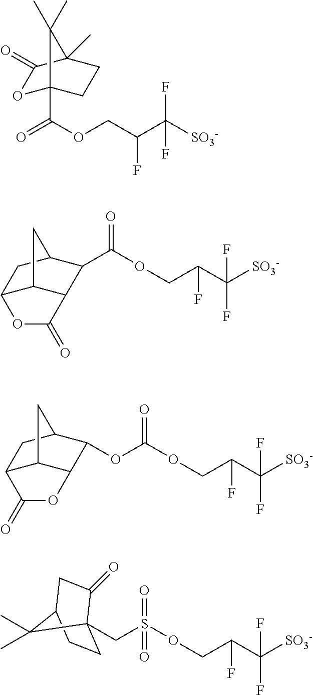

Wherein, M⁺ is preferably a sulfonium cation or an iodonium cation. When such a cation is used, the aforementioned characteristics can be further improved. In the case in which M⁺ is a sulfonium cation, the compound (A) is a sulfonium salt, and in the case in which M⁺ is an iodonium cation, the compound (A) is an iodonium salt.

Of these, a sulfonium salt is preferred as the compound (A). Preferable sulfonium cation in this case is exemplified by the cation represented by the above formula (b). Preferable examples of the sulfonium cation represented by the above formula (b) include sulfonium cations represented by the following general formulae (b1) and (b2).

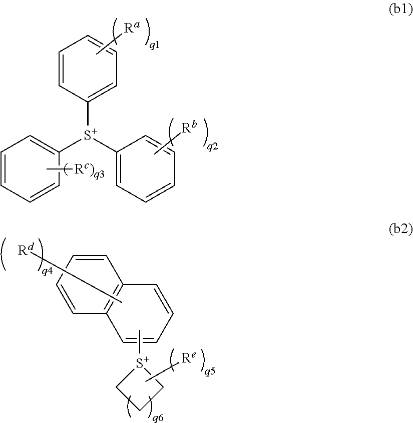

In the above formula (b1), R^{a} to R^{c} each independently represent a hydroxyl group or a halogen atom, or an alkyl group, cycloalkyl group or alkoxy group which may have a substituent, an —S—R group (wherein R represents an alkyl group or aryl group which may have a substituent), or —SO₂—R′ group (wherein R′ represents an alkyl group, cycloalkyl group, alkoxy group or aryl group which may have a substituent); q1 to q3 are each independently an integer of 0 to 5, and provided that R^{a} to R^{c} are each present in a plurality of number, the plurality of R^{a} to R^{c} are each the same or different.

In the above formula (b2), R^{d} represents a substituted or unsubstituted linear or branched alkyl group having 1 to 8 carbon atoms, or a substituted or unsubstituted aryl group having 6 to 8 carbon atoms, or two or more R^{d}s taken together represent a ring; R^{e} represents a substituted or unsubstituted linear or branched alkyl group having 1 to 7 carbon atoms, or a substituted or unsubstituted aryl group having 6 to 7 carbon atoms, or two or more R^{e}s taken together represent a ring; q4 is an integer of 0 to 7; q5 is an integer of 0 to 6; q6 is an integer of 0 to 3, provided that R^{d} and R^{e} are each present in a plurality of number, the plurality of R^{d} and R^{e} are each the same or different.

Specific examples of the sulfonium cation include cations represented by the following formulae (i-1) to (i-67).

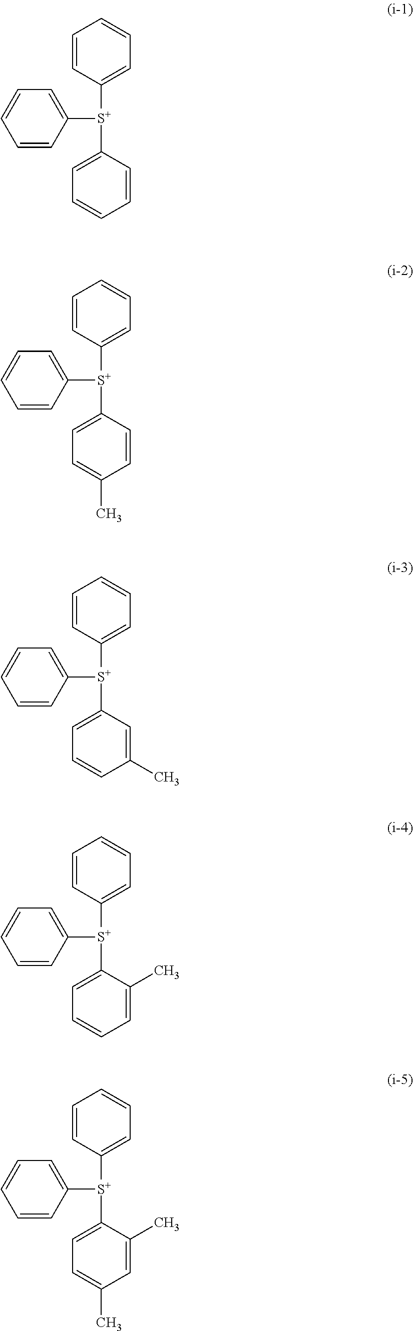 [SMILES: c1ccc([S+](c2ccccc2)c2ccccc2)cc1 ; Cc1ccc([S+](c2ccccc2)c2ccccc2)cc1 ; Cc1cccc([S+](c2ccccc2)c2ccccc2)c1 ; Cc1ccccc1[S+](c1ccccc1)c1ccccc1 ; Cc1ccc([S+](c2ccccc2)c2ccccc2)c(C)c1]

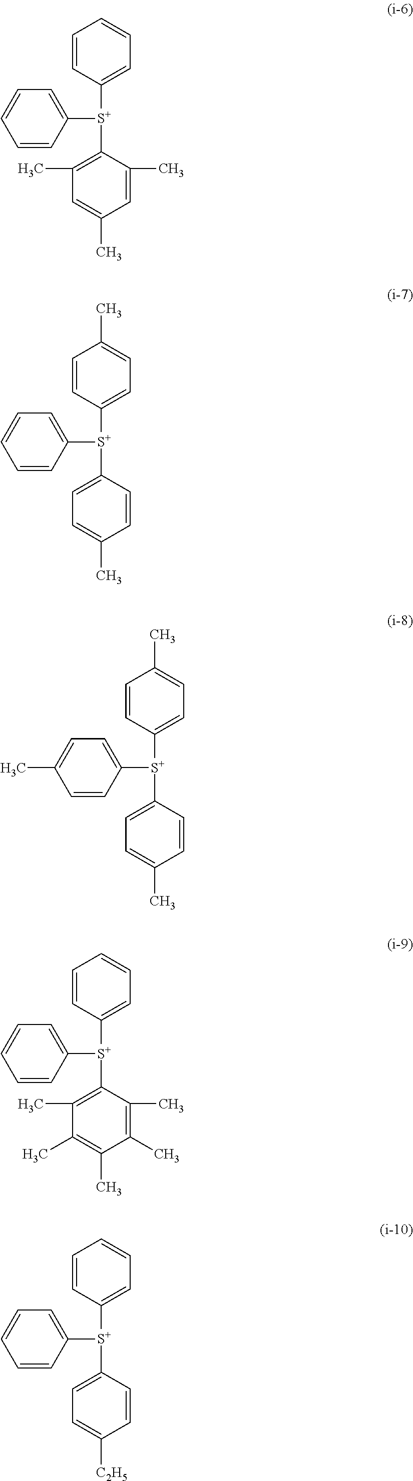

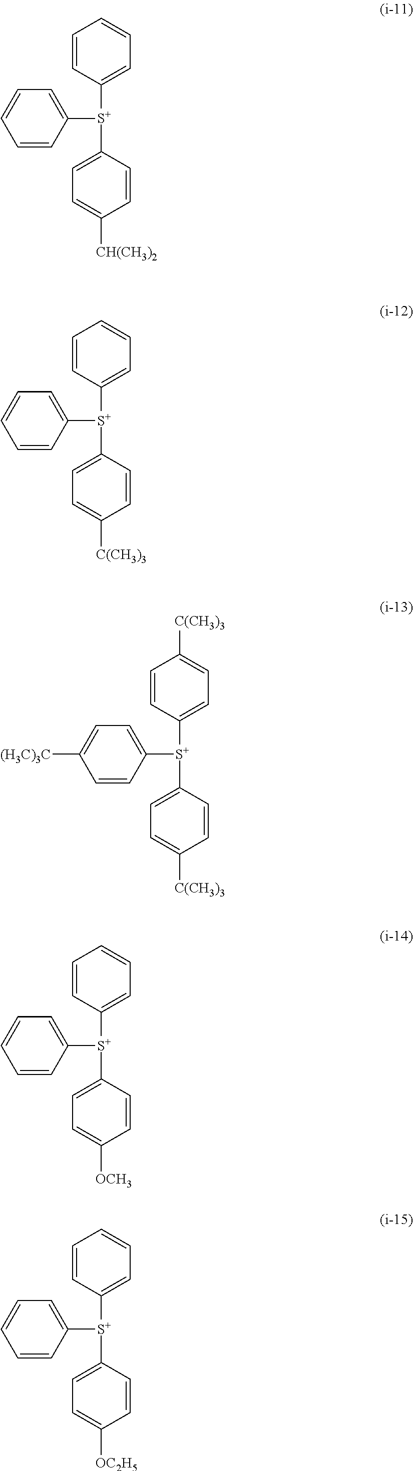 [SMILES: CC(C)c1ccc([S+](c2ccccc2)c2ccccc2)cc1 ; CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccccc2)c2ccccc2)cc1 ; CCOc1ccc([S+](c2ccccc2)c2ccccc2)cc1]

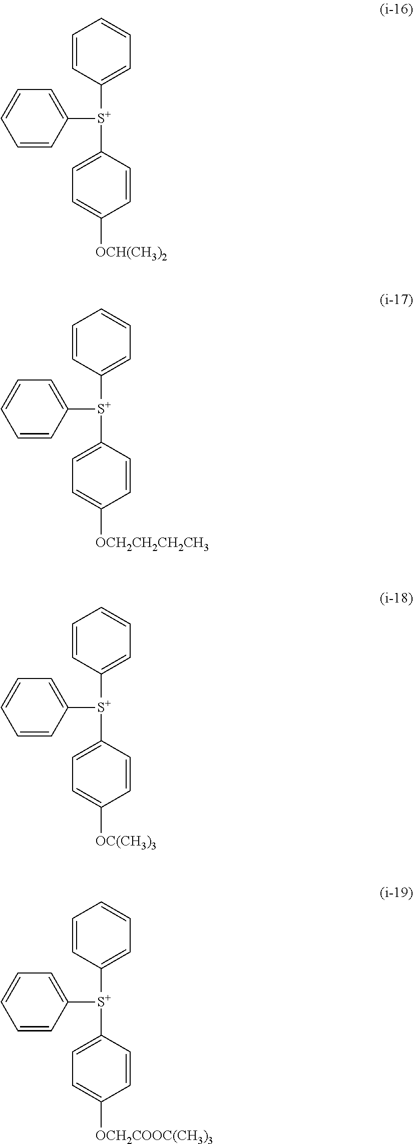

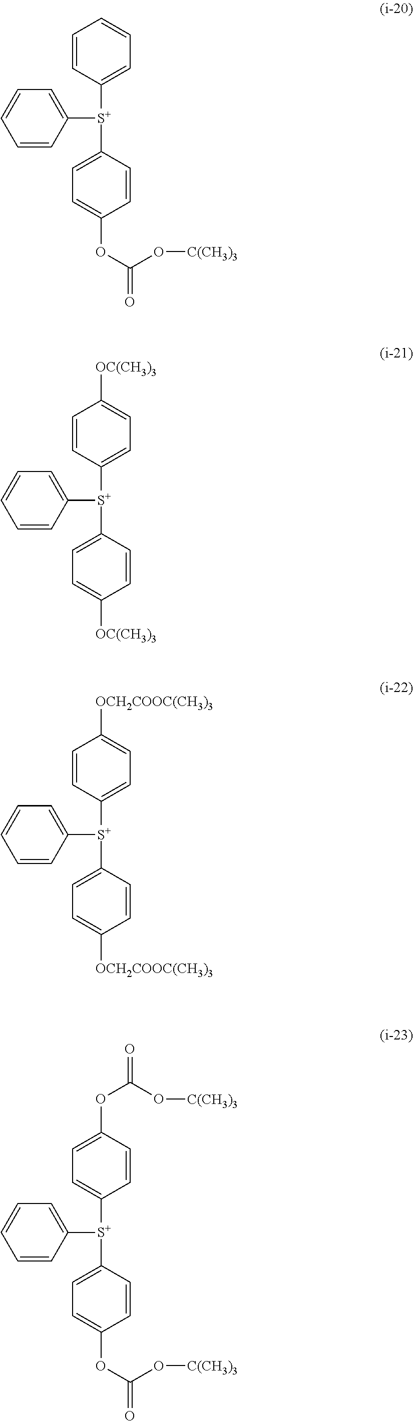

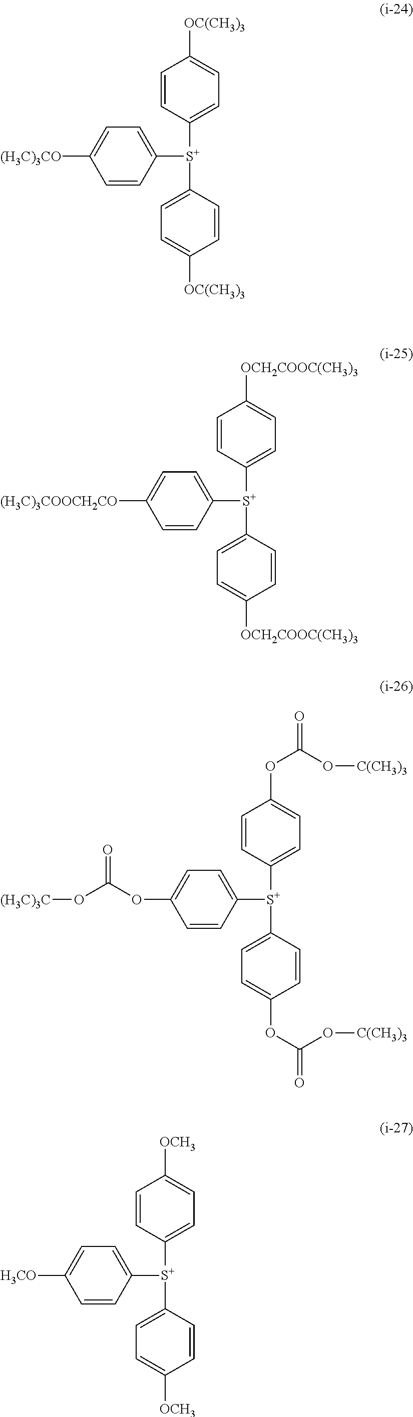

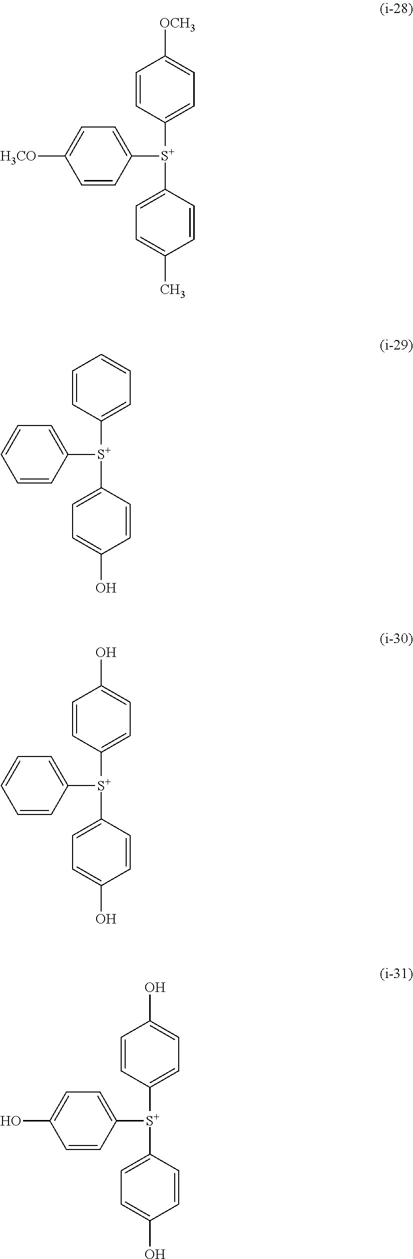 [SMILES: COc1ccc([S+](c2ccc(C)cc2)c2ccc(OC)cc2)cc1 ; Oc1ccc([S+](c2ccccc2)c2ccccc2)cc1 ; Oc1ccc([S+](c2ccccc2)c2ccc(O)cc2)cc1 ; Oc1ccc([S+](c2ccc(O)cc2)c2ccc(O)cc2)cc1]

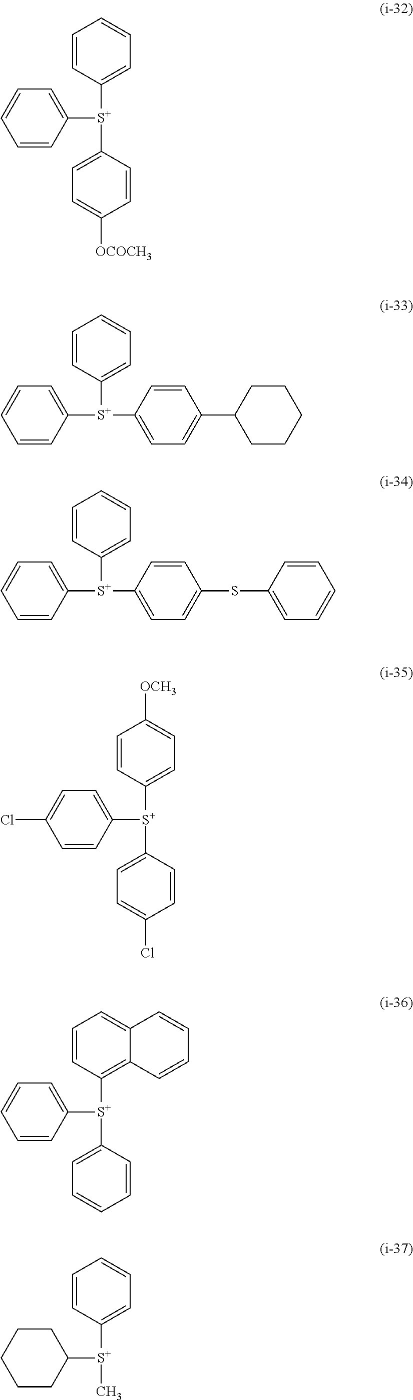

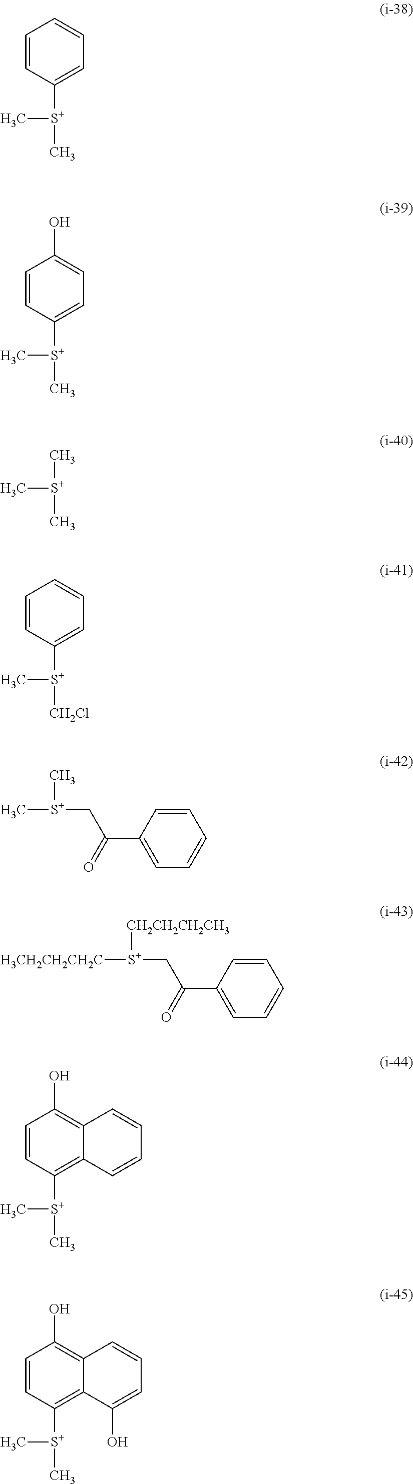

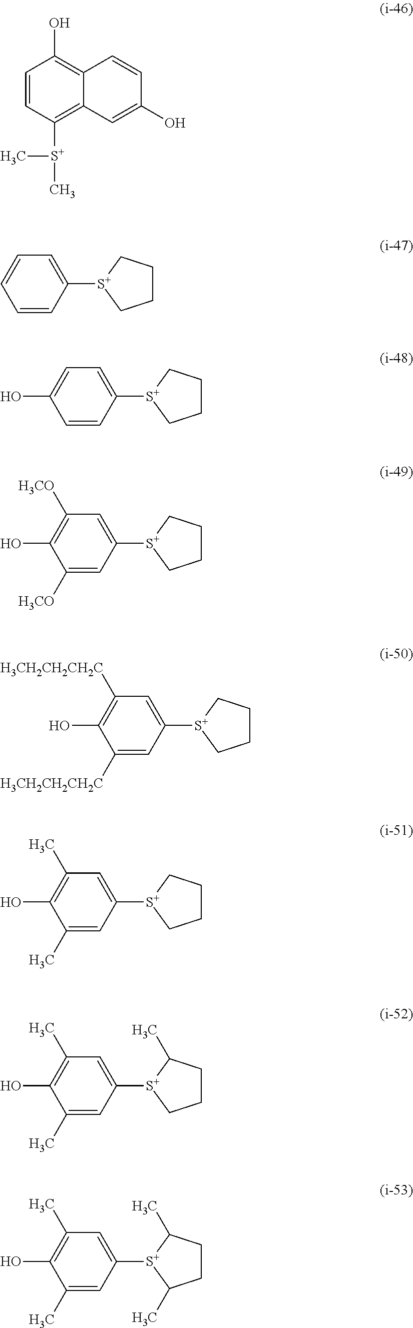

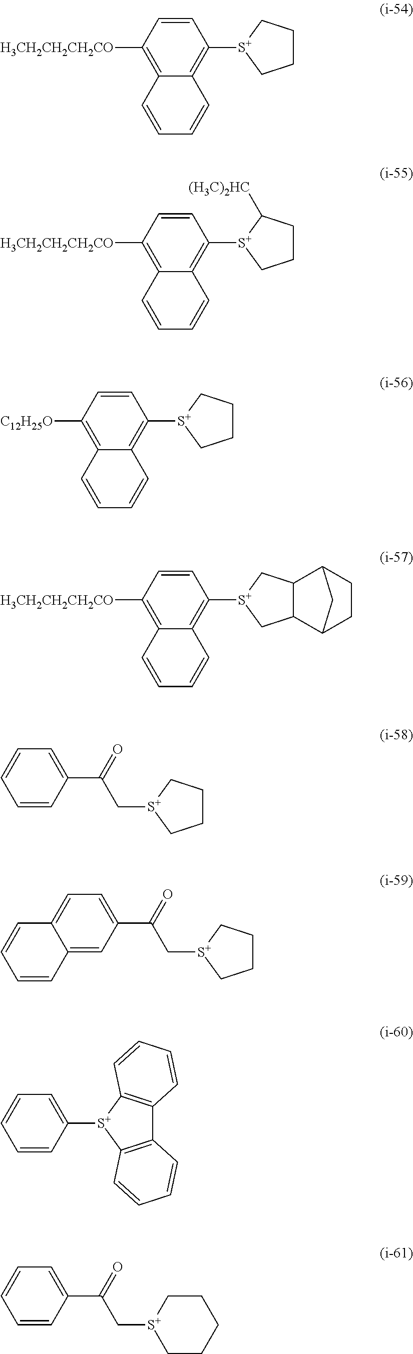

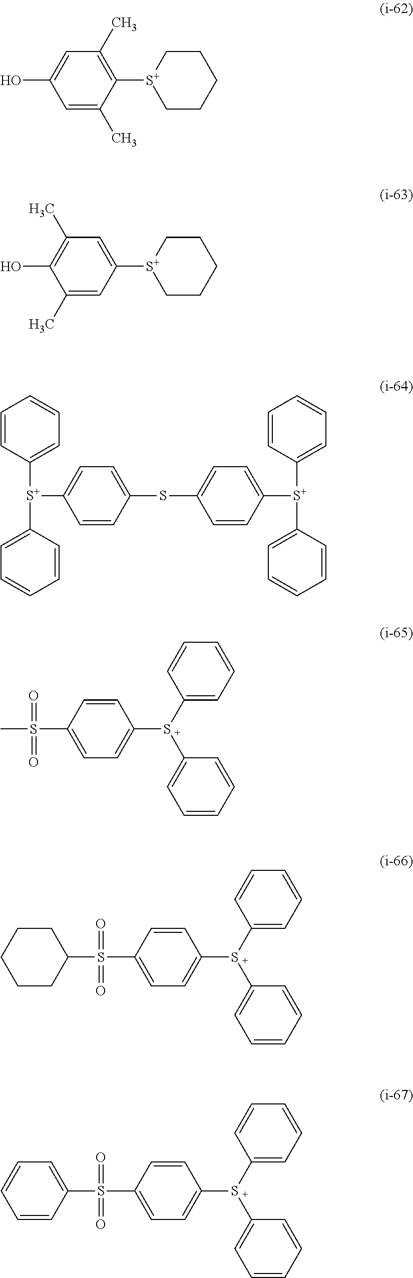

The compound (A) may be used either alone, or as a mixture of two or more thereof.

The content of the compound (A) may vary depending on the type of the compound (A) and/or the type of the following other radiation-sensitive compound which may be used occasionally, and is typically 0.1 to 40 parts by mass, preferably 5 to 40 parts by mass, and more preferably 5 to 35 parts by mass with respect to 100 parts by mass of the polymer (B) described later. In this case, when the content of the compound (A) is too low, desired effects of the embodiment of the present invention may not be satisfactorily exhibited, whereas an excessively high content may lead to deterioration of transparency against radioactive rays, pattern configuration, heat resistance and the like.

### (Synthesis Method of Compound (A))

The compound (A) may be synthesized with any well-known synthesis method, without limitation in particular.

### [(B) Polymer]

The polymer (B) serves as a base of the radiation-sensitive resin composition. In other words, the polymer (B) will be a principal component of a resist coating film formed from the radiation-sensitive resin. The polymer (B) is contained in the solid content of the radiation-sensitive resin composition of preferably no less than 50% by mass, and more preferably no less than 70% by mass. As the base polymer, a polymer which is insoluble or hardly soluble in an alkali and has an acid-dissociable group and which becomes easily soluble in alkali when the acid-dissociable group dissociates is suitably used. It is to be noted that the term “acid-dissociable group” means a group that substitutes for a hydrogen atom in a polar functional group such as a hydroxyl group or a carboxy group, for example, and that dissociates in the presence of an acid.

The term “insoluble or hardly soluble in alkali” as referred to herein means a property that no less than 50% of the initial film thickness of a coating remains after development in the case where the coating formed using only the polymer containing an acid-dissociable group is developed in place of the resist coating film under alkali development conditions employed in forming a resist pattern from a resist coating film formed using a radiation-sensitive resin composition that contains the polymer containing an acid-dissociable group.

When the polymer (C) described later is used, the proportion of the fluorine atom(s) contained in the polymer (B) is typically less than 5% by mass, preferably 0 to 4.9% by mass, and more preferably 0 to 4% by mass. It is to be noted that the proportion of the fluorine atom(s) contained can be determined by ¹³C-NMR. When the proportion of the fluorine atom(s) contained in the polymer (B) falls within the above range, water repellency of the surface of the resist coating film formed with the radiation-sensitive resin composition containing the polymer (B) and the polymer (C) can be improved, and necessity of separately forming the upper layer film in liquid immersion lithography is obviated.

### (Structural Unit (1))

The polymer (B) has at least one structural unit (1) selected from the group consisting of a structural unit derived from (meth)acrylate that includes a lactone skeleton (1-1), a structural unit derived from (meth)acrylate that includes a cyclic carbonate skeleton (1-2), a structural unit derived from (meth)acrylate that includes a sultone skeleton (1-3), and a structural unit derived from (meth)acrylate that includes a polar group (1-4). Due to having the structural unit (1), the radiation-sensitive resin composition can provide improved adhesiveness to the substrate of the pattern to be obtained, and improved balance of LWR and MEEF, etc.

### (Structural Unit (1-1))

Preferable structural unit (1-1) is exemplified by structural units represented by the following formulae.

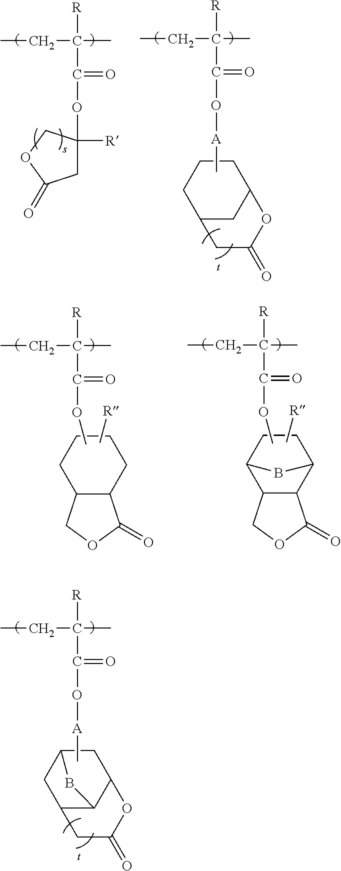

In the above formulae, R and R′ each independently represent a hydrogen atom or a methyl group; R″ represents a hydrogen atom or a methoxy group; A is a single bond or a methylene group; B is a methylene group or an oxygen atom; and s and t are each independently 0 or 1.

The structural unit (1-1) is particularly preferably a structural unit represented by the following formulae.

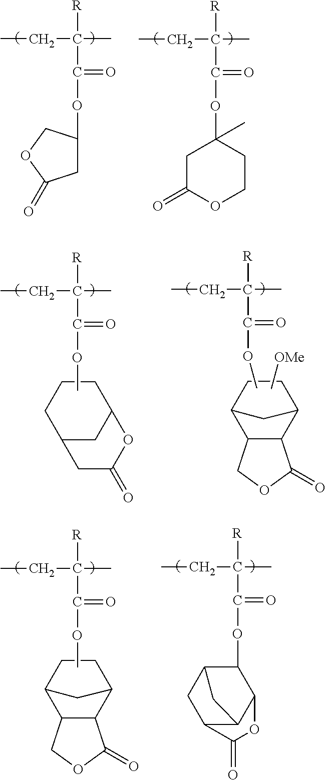

In the above formulae, R represents a hydrogen atom or a methyl group.

The content of the structural unit (1-1) in the polymer (B) is preferably 30 to 70 mol %, and more preferably 35 to 55 mol %.

### (Structural Unit (1-2))

Preferable structural unit (1-2) is exemplified by structural units represented by the following formula.

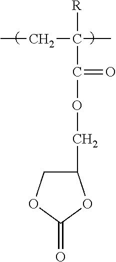

In the above formula, R represents a hydrogen atom or a methyl group.

The content of the structural unit (1-2) in the polymer (B) is preferably 30 to 70 mol %, and more preferably 35 to 55 mol %.

### (Structural Unit (1-3))

Preferable structural unit (1-3) is exemplified by structural units represented by the following formula.

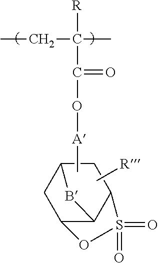

In the above formula, R represents a hydrogen atom or a methyl group; R′″ represents a hydrogen atom, a methyl group or an ethyl group; A′ is a single bond or —CH₂—COO—; and B′ is a methylene group, an ethylene group, a sulfur atom or an oxygen atom.

The structural unit (1-3) is particularly preferably a structural unit represented by the following formulae.

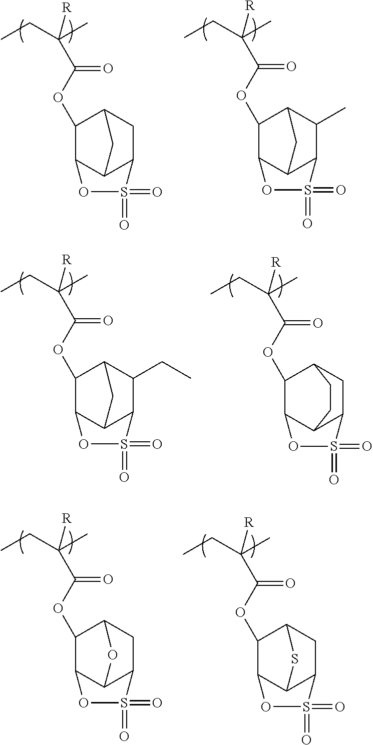

In the above formulae, R represents a hydrogen atom or a methyl group.

The content of the structural unit (1-3) in the polymer (B) is preferably 10 to 70 mol %, and more preferably 15 to 55 mol %.

### (Structural Unit (1-4))

Examples of the polar group in the structural unit (1-4) include a hydroxyl group, a carboxy group, a cyano group, an amino group, —CO—, and the like, and in particular, a hydroxyl group is preferred. Preferable structural unit (1-4) is exemplified by structural units represented by the following formulae.

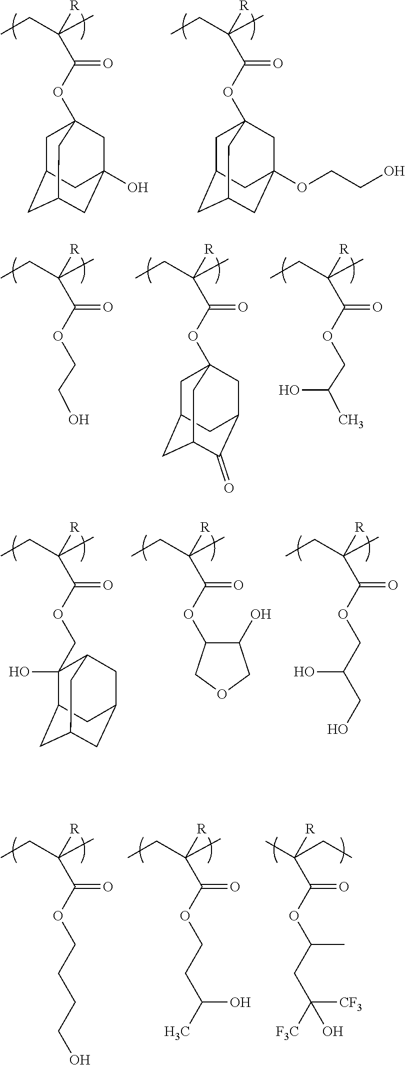

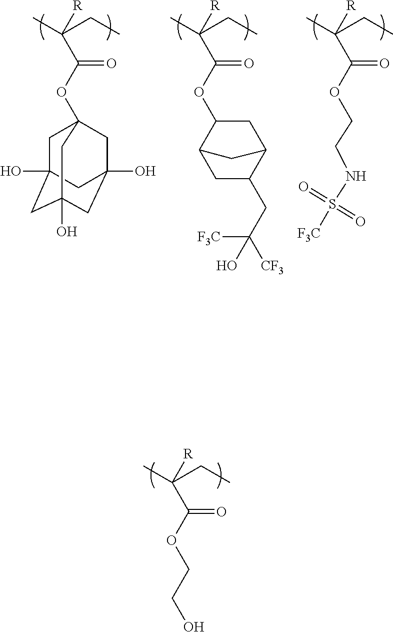

In the above formulae, R represents a hydrogen atom or a methyl group.

The content of the structural unit (1-4) in the polymer (B) is preferably 3 to 20 mol %, and more preferably 5 to 15 mol %.

### (Structural Unit (2))

The polymer (B) preferably has a structural unit (2). The structural unit (2) includes an acid-dissociable group.

In the formula (2), R¹⁰ represents a hydrogen atom or a methyl group; R¹¹ each independently represents a linear or branched alkyl group having 1 to 4 carbon atoms, or an alicyclic hydrocarbon group having 4 to 20 carbon atoms, wherein, two R¹¹s optionally taken together represent an alicyclic hydrocarbon group having 4 to 20 carbon atoms together with the carbon atom to which the R¹¹s bond.

Examples of the alkyl group having 1 to 4 carbon atoms represented by the R¹¹ include a methyl group, an ethyl group, a n-propyl group, a n-butyl group, and the like. Examples of the alicyclic hydrocarbon group having 4 to 20 carbon atoms represented by the R¹¹, or the alicyclic hydrocarbon group having 4 to 20 carbon atoms represented by two R¹¹s taken together with the carbon atom to which the R¹¹s bond include, a cyclopentyl group, a cyclohexyl group, a cyclooctyl group, an adamantyl group, a norbornyl group, and the like.

The structural unit (2) is preferably represented by the following formulae (2-1) to (2-17), and is more preferably represented by the following formulae (2-3), (2-4), (2-9), (2-12) and (2-13). These may be included either one type alone, or two or more types may be included.

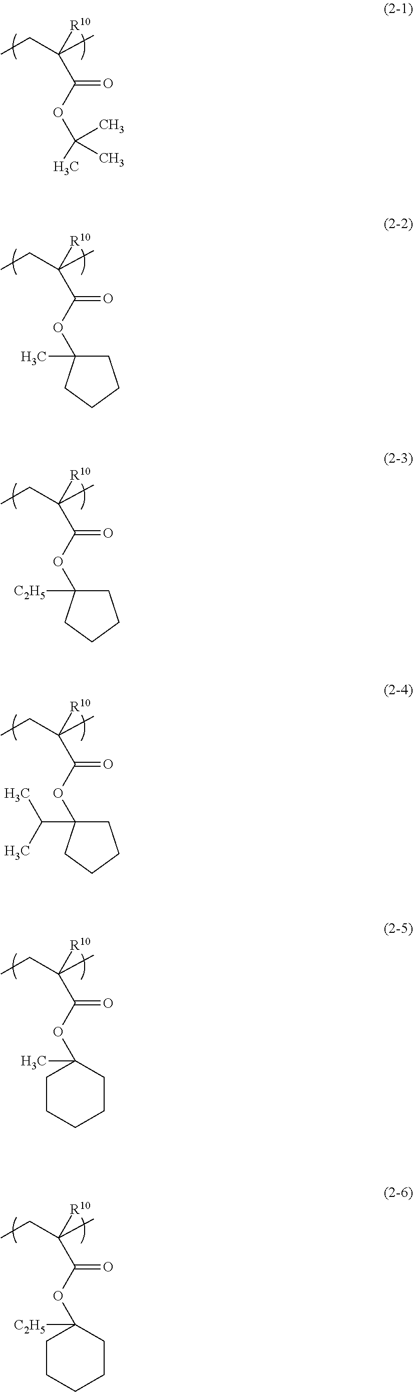

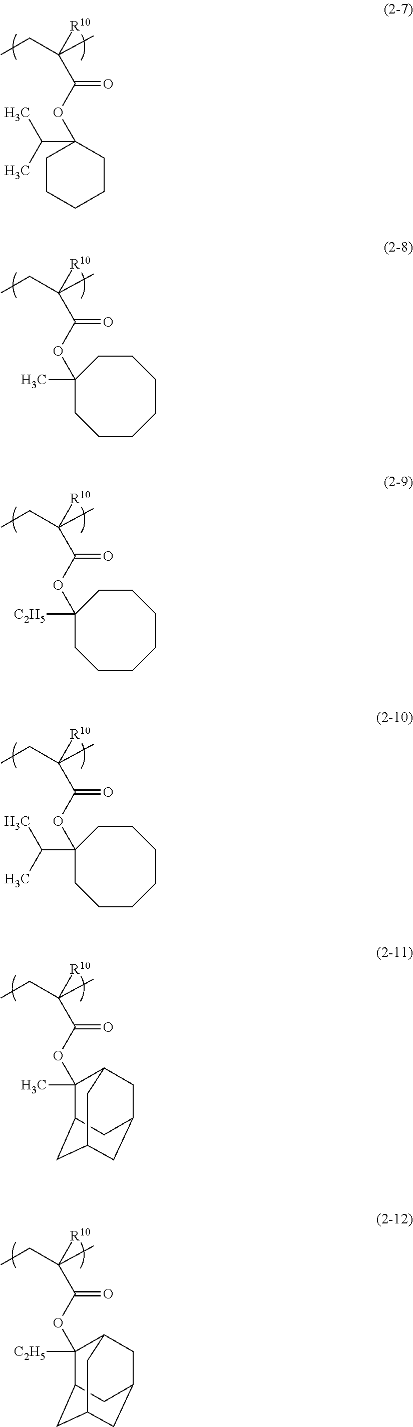

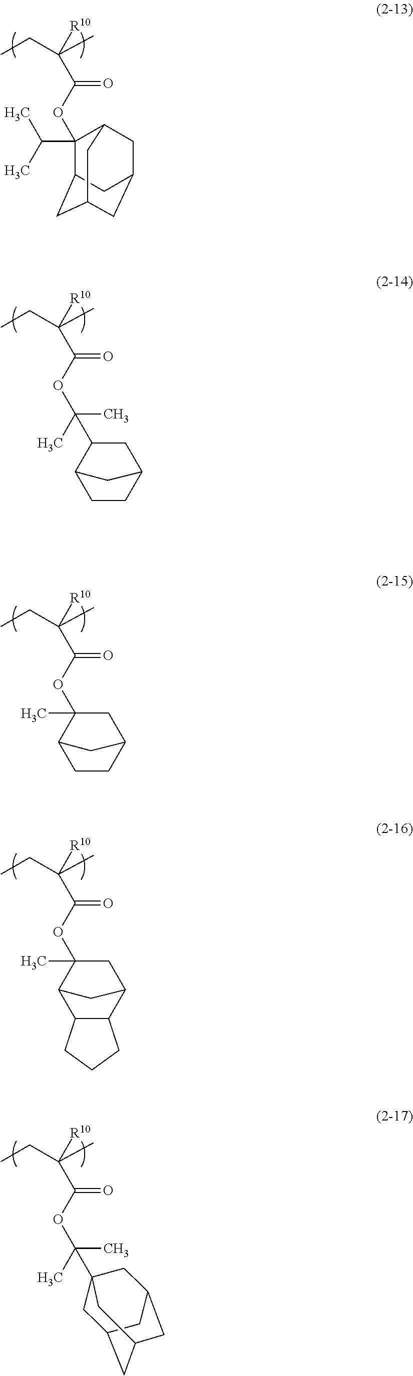

In the above formulae (2-1) to (2-17), R¹⁰ is as defined in the above formula (2).

The polymer (B) may further have other structural unit. Examples of the other structural unit include structural units derived from (meth)acrylic acid, and (meth)acrylate esters such as (meth)adamantyl acrylate and (meth)norbornyl acrylate, and the like.

The molecular weight of the polymer (B) is not particularly limited, and may be appropriately selected. The polystyrene equivalent weight average molecular weight (hereinafter, may be referred to as “Mw”) as determined by gel permeation chromatography (GPC) is typically 1,000 to 500,000, preferably 2,000 to 400,000, and more preferably 3,000 to 300,000.

Also, a ratio (Mw/Mn) of the Mw to a polystyrene equivalent number average molecular weight as determined by GPC (hereinafter, may be referred to as “Mn”) of the polymer (B) is not particularly limited, and may be appropriately selected. The ratio (Mw/Mn) of the polymer (B) is typically 1 to 5, preferably 1 to 3, and more preferably 1 to 2. When the polymer having the ratio of Mw/Mn falling within this range, the resulting resist can have superior resolving ability. In the radiation-sensitive resin composition of the embodiment of the present invention, the polymer (B) may be used either alone, or as a mixture of two or more thereof.

### (Synthesis Method of Polymer (B))

Although the synthesis method of the polymer (B) is not particularly limited, the polymer (B) may be synthesized by, for example, a method in which one or more types of acid-dissociable group is/are introduced into an acidic functional group in an alkali-soluble polymer synthesized beforehand; a method in which one or more types of polymerizable unsaturated monomer having an acid-dissociable group is/are polymerized together with one or more other polymerizable unsaturated monomer(s); a method in which one or more types of polycondensible component having an acid-dissociable group is/are polycondensed together with other polycondensible component, or the like.

As a monomer compound which may be used in the synthesis of the polymer (B), a compound containing at least any one of (meth)acrylate that includes a lactone skeleton, (meth)acrylate that includes a cyclic carbonate skeleton, (meth)acrylate that includes a sultone skeleton, and (meth)acrylate that includes a polar group is exemplified. In addition, it is also preferred that (meth)acrylate having an acid-dissociable group is further used as the monomer compound.

In the polymerization of the polymerizable unsaturated monomer in synthesizing the alkali-soluble polymer, and the polymerization of the polymerizable unsaturated monomer having an acid-dissociable group, an adequate polymerization system such as block polymerization, solution polymerization, precipitation polymerization, emulsion polymerization, suspension polymerization or block-suspension polymerization may be carried out with a polymerization initiator or polymerization catalyst such as a radical polymerization initiator, an anion polymerization catalyst, a coordinated anion polymerization catalyst or a cation polymerization catalyst appropriately selected in accordance with the polymerizable unsaturated monomer and the type of the reaction medium employed, and the like.

Moreover, polycondensation of the polycondensible component having an acid-dissociable group may be carried out in a water medium or a mixed medium of water and a hydrophilic solvent in the presence of preferably an acidic catalyst.

### [(C) Polymer]

The radiation-sensitive resin composition may also contain (C) a fluorine-containing polymer as a water repellent additive. When a resist coating film is formed using the composition containing the polymer (B) and the polymer (C), distribution of the polymer (C) is likely to increase on the surface of the resist coating film resulting from the water repellency of the polymer (C). In other words, the polymer (C) is unevenly distributed in the surface layer of the resist coating film. Therefore, when the polymer (C) is used, it is not necessary to separately form an upper layer film for the purpose of blocking the resist coating film from the liquid for liquid immersion lithography, and thus the radiation-sensitive resin composition containing the polymer (C) can be suitably used in liquid immersion lithography process.

### (Structural Unit (C1))

The polymer (C) is not particularly limited as long as it includes a fluorine atom in the molecule, and preferably has a structural unit that includes a fluorine atom (hereinafter, may be referred to as “structural unit (C1)”). Specific examples of the structural unit (C1) include a structural unit represented by the following formula (a1-1) (hereinafter, may be referred to as “structural unit (a1-1)”), a structural unit represented by the following formula (a1-2) (hereinafter, may be referred to as “structural unit (a1-2)”), and a structural unit represented by the following formula (a1-3) (hereinafter, may be referred to as “structural unit (a1-3)”).

When the polymer (C) has any of the structural units (a1-1) to (a1-3), elution of an acid generating agent, an acid diffusion control agent, etc. in the resist coating film into a liquid for liquid immersion lithography is suppressed, and water droplet originated from a liquid for liquid immersion lithography is less likely to remain on the resist coating film due to improvement of a receding contact angle between the resist coating film and the liquid for liquid immersion lithography, whereby generation of defects resulting from a liquid for liquid immersion lithography can be inhibited.

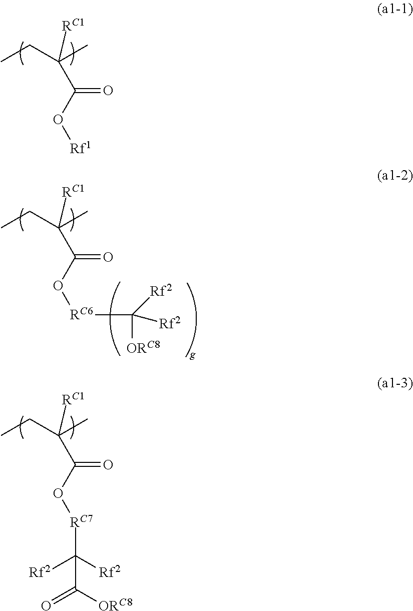

In the formulae (a1-1) to (a1-3), R^{C1} each independently represents a hydrogen atom, a methyl group or a trifluoromethyl group. In the formula (a1-1), Rf¹ represents a fluorinated alkyl group having 1 to 30 carbon atoms. In the formula (a1-2), R^{C6} represents a linking group having a valency of (g+1); and g is an integer of 1 to 3, wherein when g is 1, R^{C6} may be a single bond. In the formula (a1-3), R^{C7} represents a bivalent linking group. In the formulae (a1-2) and (a1-3), R^{C8} each independently represents a hydrogen atom or a monovalent organic group; and Rf² each independently represents a hydrogen atom, a fluorine atom or a fluorinated alkyl group having 1 to 30 carbon atoms, but any case where all Rf²s represent a hydrogen atom is excluded.

(Structural Unit (a1-1))

Rf¹ in the above formula (a1-1) is exemplified by a linear or branched alkyl group having 1 to 6 carbon atoms substituted with at least one fluorine atom, monovalent alicyclic hydrocarbon group having 4 to 20 carbon atoms substituted with at least one fluorine atom, or groups derived therefrom.

Examples of preferable monomer that gives the structural unit (a1-1) include trifluoromethyl(meth)acrylic acid esters, 2,2,2-trifluoroethyl(meth)acrylic acid esters, perfluoroethyl(meth)acrylic acid esters, perfluoro n-propyl(meth)acrylic acid esters, perfluoro i-propyl(meth)acrylic acid esters, perfluoro n-butyl(meth)acrylic acid esters, perfluoro i-butyl(meth)acrylic acid esters, perfluoro t-butyl(meth)acrylic acid esters, 2-(1,1,1,3,3,3-hexafluoropropyl)(meth)acrylic acid esters, 1-(2,2,3,3,4,4,5,5-octafluoropentyl)(meth)acrylic acid esters, perfluorocyclohexylmethyl(meth)acrylic acid esters, 1-(2,2,3,3,3-pentafluoropropyl)(meth)acrylic acid esters, 1-(3,3,4,4,5,5,6,6,7,7,8,8,9,9,10,10,10-heptadecafluorodecyl)(meth)acrylic acid esters, 1-(5-trifluoromethyl-3,3,4,4,5,6,6,6-octafluorohexyl)(meth)acrylic acid esters, and the like.

(Structural Units (a1-2) and (a1-3))

The polymer (C) may have the structural unit (a1-2) or the structural unit (a1-3) as the structural unit that includes a fluorine atom.

The monovalent organic group represented by the R^{C8} is exemplified by a monovalent hydrocarbon group having 1 to 30 carbon atoms, an acid-dissociable group, and an alkali-dissociable group.

The monovalent hydrocarbon group having 1 to 30 carbon atoms is exemplified by a linear or branched monovalent hydrocarbon group having 1 to 10 carbon atoms, and a monovalent cyclic hydrocarbon group having 3 to 30 carbon atoms.

Examples of the linear or branched monovalent hydrocarbon group having 1 to 10 carbon atoms include a methyl group, an ethyl group, a n-propyl group, a n-butyl group, an i-propyl group, an i-butyl group, a sec-butyl group, and the like. Examples of the monovalent cyclic hydrocarbon group having 3 to 30 carbon atoms include a cyclopropyl group, a cyclobutyl group, a cyclopentyl group, a cyclohexyl group, and the like. These hydrocarbon groups exclude acid-dissociable groups and alkali-dissociable groups described later. Also, the hydrocarbon group may have a substituent.

Specific examples of the acid-dissociable group include a t-butoxycarbonyl group, a tetrahydropyranyl group, a tetrahydrofuranyl group, a (thiotetrahydropyranylsulfanyl)methyl group, a (thiotetrahydrofuranylsulfanyl)methyl group, as well as an alkoxy-substituted methyl group, an alkylsulfanyl-substituted methyl group, and the like. It is to be noted that the alkoxy group (substituent) in the alkoxy-substituted methyl group is exemplified by an alkoxy group having 1 to 4 carbon atoms. In addition, the alkyl group (substituent) in the alkylsulfanyl-substituted methyl group is exemplified by an alkyl group having 1 to 4 carbon atoms.

Furthermore, the acid-dissociable group is exemplified by a group represented by a general formula of: [—C(R^{g})₃]. Wherein, in the formula, three R^{g}s may be similarly defined to R¹¹ in the above formula (2).

In addition, among these acid-dissociable groups, the group represented by the formula of: [—C(R^{g})₃], a t-butoxycarbonyl group, and an alkoxy-substituted methyl group are preferred. In particular, in the structural unit (a1-2), a t-butoxycarbonyl group and an alkoxy-substituted methyl group are preferred. In the structural unit (a1-3), an alkoxy-substituted methyl group and the group represented by the formula of: [—C(R^{g})₃] are preferred.

When the structural unit (a1-2) or structural unit (a1-3) having an acid-dissociable group is used, use in combination with the polymer (B1) described above provides a preferable positive type radiation-sensitive resin composition since improvement of the solubility of the polymer (C) at the site exposed with a radioactive ray is enabled. This benefit is believed to result from generation of a polar group through a reaction with an acid generated at a light-exposed site of the resist coating film in the exposure step of a method for forming a resist pattern described later.

The “alkali-dissociable group” as referred to means a group that substitutes for a hydrogen atom in a polar functional group such as for example, a hydroxyl group or a carboxy group and is dissociated in the presence of an alkali.

Such an alkali-dissociable group is not particularly limited as long as the aforementioned properties are exhibited, and the alkali-dissociable group in the above formula (a1-2) is exemplified by groups represented by the following formula (R1-1).

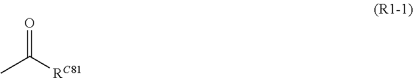

In the above formula (R1-1), R^{C81} represents a hydrocarbon group having 1 to 10 carbon atoms in which at least one hydrogen atom(s) is/are substituted by a fluorine atom. R^{C81} may be similarly defined to the aforementioned Rf¹ which has 1 to 10 carbon atoms.

R^{C81} is preferably a linear or branched perfluoroalkyl group having 1 to 10 carbon atoms in which all hydrogen atoms in the hydrocarbon group are substituted by a fluorine atom, and more preferably a trifluoromethyl group.

Also, the alkali-dissociable group in the above formula (a1-3) is exemplified by groups represented by the following formulae (R1-2) to (R1-4).

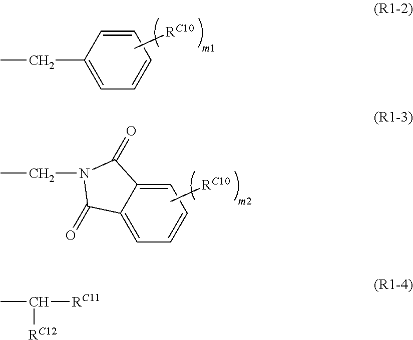

In the above formulae (R1-2) and (R1-3), R^{C10} represents a halogen atom, or an alkyl group, alkoxy group, acyl group or acyloxy group having 1 to 10 carbon atoms; m1 is an integer of 0 to 5; m2 is an integer of 0 to 4, and provided that R^{C10} is present in a plurality of number, the plurality of R^{C10}s are each the same or different.

In the above formula (R1-4), R^{C11} and R^{C12} each independently represent a hydrogen atom or an alkyl group having 1 to 10 carbon atoms, or R^{c11} and R^{C12} taken together represent an alicyclic structure having 4 to 20 carbon atoms.

In the above formulae (R1-2) and (R1-3), examples of the halogen atom represented by R^{C11} include a fluorine atom, a chlorine atom, a bromine atom, an iodine atom, and the like. Of these, a fluorine atom is preferred.

In the above formulae (R1-2) and (R1-3), examples of the alkyl group having 1 to 10 carbon atoms represented by R^{C10} include a methyl group, an ethyl group, a n-propyl group, a n-butyl group, an i-propyl group, an i-butyl group, a sec-butyl group, and the like.

In the above formula (R1-4), examples of the alkyl group having 1 to 10 carbon atoms represented by R^{C111} or R^{C12} include groups exemplified in connection with the R^{C10} above.

Also, examples of the group that has an alicyclic structure represented by R^{C111} and R^{C12} taken together include a cyclopentyl group, a cyclopentylmethyl group, a 1-(1-cyclopentylethyl) group, a 1-(2-cyclopentylethyl) group, a cyclohexyl group, a cyclohexylmethyl group, a 1-(1-cyclohexylethyl) group, a 1-(2-cyclohexylethyl) group, a cycloheptyl group, a cycloheptylmethyl group, a 1-(1-cycloheptylethyl) group, a 1-(2-cycloheptylethyl) group, a 2-norbornyl group, and the like.

Specific examples of the group represented by the above formula (R1-4) include a methyl group, an ethyl group, a 1-propyl group, a 2-propyl group, a 1-butyl group, a 2-butyl group, a 1-pentyl group, a 2-pentyl group, a 3-pentyl group, a 1-(2-methylbutyl) group, a 1-(3-methylbutyl) group, a 2-(3-methylbutyl) group, a neopentyl group, a 1-hexyl group, a 2-hexyl group, a 3-hexyl group, a 1-(2-methylpentyl) group, a 1-(3-methylpentyl) group, a 1-(4-methylpentyl) group, a 2-(3-methylpentyl) group, a 2-(4-methylpentyl) group, a 3-(2-methylpentyl) group, and the like. Of these, a methyl group, an ethyl group, a 1-propyl group, a 2-propyl group, a 1-butyl group and a 2-butyl group are preferred.

Including the alkali-dissociable group in the structural unit (a1-2) or the structural unit (a1-3) in the polymer (C) is preferred since an affinity of the polymer (C) to a developer solution can be improved. This benefit is believed to result from generation of a polar group through a reaction of the polymer (C) with a developer solution in the development step of a method for forming a pattern described later.

In the formulae (a1-2) and (a1-3), provided that R^{C8} represents a hydrogen atom, the structural units (a1-2) and (a1-3) will have a hydroxyl group and a carboxy group which are each a polar group. When the polymer (C) has such a structural unit, an affinity of the polymer (C) to the developer solution can be improved in the development step of a method for forming a pattern described later.

The linking group having a valency of (g+1) represented by the R^{C6} is exemplified by a hydrocarbon group having 1 to 30 carbon atoms and having a valency of (g+1), a group (α) having a valency of (g+1) in which the hydrocarbon group having 1 to 30 carbon atoms and having a valency of (g+1) is combined with an oxygen atom, a sulfur atom, an imino group, a carbonyl group, —CO—O— or —CO—NH—, or a group (β) having a valency of (g+1) in which the group (α) is combined with a bivalent hydrocarbon group having 1 to 30 carbon atoms. When g is 2 or 3, a plurality of groups represented by the following formula in the formula (a1-2) may be the same or different.

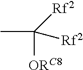

Examples of the hydrocarbon group having 1 to 30 carbon atoms and having a valency of (g+1) represented by the R^{C6} include:

as hydrocarbon groups having a chain structure, hydrocarbon groups having a valency of (g+1) and having a structure obtained by removing (g+1) hydrogen atoms from a chain hydrocarbon having 1 to 10 carbon atoms such as methane, ethane, propane, butane, 2-methylpropane, pentane, 2-methylbutane, 2,2-dimethylpropane, hexane, heptane, octane, nonane or decane; and

as hydrocarbon groups having a cyclic structure, hydrocarbon groups having a valency of (g+1) and having a structure obtained by removing (g+1) hydrogen atoms from an alicyclic hydrocarbon having 4 to 20 carbon atoms such as cyclobutane, cyclopentane, cyclohexane, bicyclo[2.2.1]heptane, bicyclo[2.2.2]octane, tricyclo[5.2.1.02,6]decane or tricyclo[3.3.1.13,7]decane, and hydrocarbon groups having a valency of (g+1) and having a structure obtained by removing (g+1) hydrogen atoms from an aromatic hydrocarbon having 6 to 30 carbon atoms such as benzene or naphthalene, and the like.

Examples of the linking group having a valency of (g+1) represented by the R^{C6} include groups represented by the following general formulae.

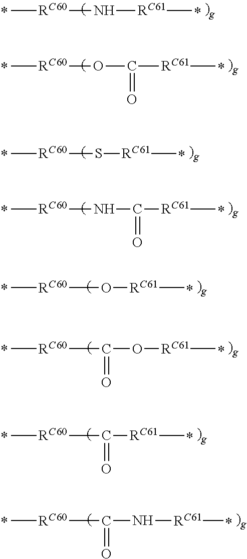

In the above formulae, R^{C60} each independently represents hydrocarbon group having 1 to 30 carbon atoms and having a valency of (g+1); and R^{C61} each independently represents single bond, a bivalent chain hydrocarbon group having 1 to 10 carbon atoms, a bivalent alicyclic hydrocarbon group having 4 to 20 carbon atoms or a bivalent aromatic hydrocarbon group having 6 to 30 carbon atoms. Examples of the group represented by the R^{C60} include groups similar to the hydrocarbon group having 1 to 30 carbon atoms and having a valency of (g+1) exemplified in connection with the definition of the R^{C6}, and the like. Of the groups represented by the R^{C61}, examples of the bivalent chain hydrocarbon group having 1 to 10 carbon atoms, the bivalent alicyclic hydrocarbon group having 4 to 20 carbon atoms and the bivalent aromatic hydrocarbon group having 6 to 30 carbon atoms include groups obtained by removing two hydrogen atoms from each hydrocarbon corresponding to each of the hydrocarbon group exemplified in connection with the definition of the R^{C6}.

Also, R^{C6} may have a substituent.

The linking group represented by R^{C7} in the general formula (a1-3) may be similarly defined to the R^{C6} above wherein g is 1.

In the above formula (a1-2) or (a1-3), Rf² represents a hydrogen atom, a fluorine atom or a fluorinated hydrocarbon group having 1 to 30 carbon atoms, wherein, any case where all Rf²s represent a hydrogen atom is excluded. The fluorinated hydrocarbon group having 1 to 30 carbon atoms represented by Rf² is exemplified by groups obtained by substituting by a fluorine atom a part or all hydrogen atoms included in a hydrocarbon group having 1 to 30 carbon atoms such as a methyl group or an ethyl group, and the like.

In the above formulae (a1-2) and (a1-3), a partial structure represented by the following formula is exemplified by those represented by the following formulae (1) to (5). Of these, in the above formula (a1-2), a structure represented by the following formula (5) is preferred, whereas in the above formula (a1-3), a structure represented by the following formula (3) is preferred.

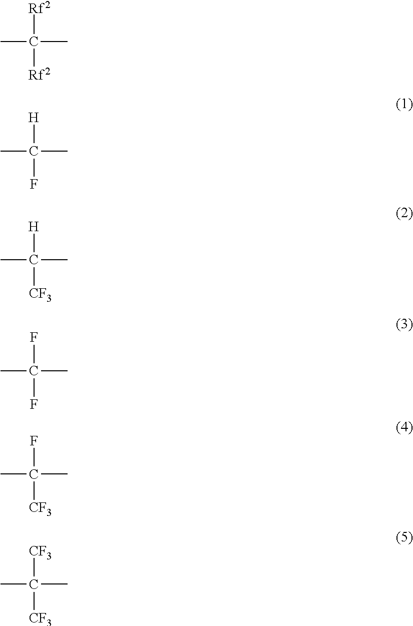

Specific examples of the structural unit (a1-2) include structural units represented by the following formulae (a1-2-1) and (a1-2-2).

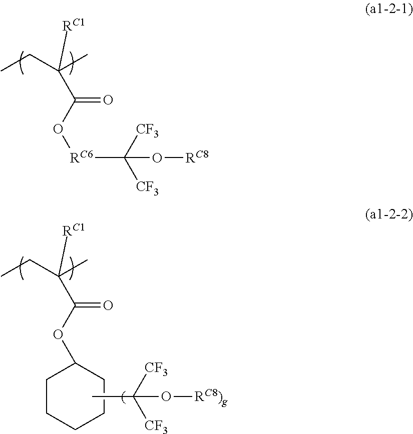

In the above formulae (a1-2-1) and (a1-2-2), R^{C1}, R^{C6}, R^{C8} and g are as defined in connection with the above general formula (a2-1).

Examples of compounds that give the structural unit (a1-2) include compounds represented by the following formulae.

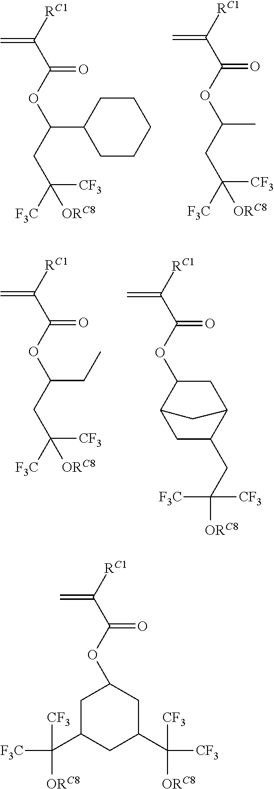

In the above formulae, R^{C1} and R^{C8} are as defined in connection with the above general formula (a1-2).

The compound represented by the above formula, in which R^{C8} represents an acid-dissociable group or an alkali-dissociable group can be synthesized using as a raw material, for example, a compound represented by each formula in which R^{C8} represents a hydrogen atom. Referring to an exemplary compound in which R^{C8} is represented by the above formula (R1-1), the intended compound represented by the above formula can be formed by fluoroacylating a compound represented by each formula in which R^{C8} represents a hydrogen atom according to a conventionally well-known method. Exemplary method of synthesizing a compound in which R^{C8} represents an acid-dissociable group or an alkali-dissociable group may include, for example, 1) a method including allowing an alcohol and a fluorocarboxylic acid to be condensed in the presence of an acid, thereby permitting esterification, 2) a method including allowing an alcohol and a fluorocarboxylic acid halide to be condensed in the presence of a base, thereby permitting esterification, and the like.

Specific examples of the structural unit (a1-3) include structural units represented by the following formula (a1-3-1).

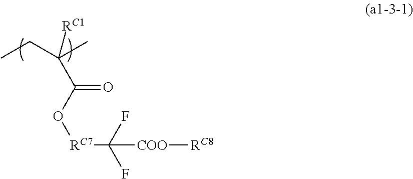

In the above formula (a1-3-1), R^{C1}, R^{C7} and R^{C8} are as defined in connection with the above general formula (a1-3). Examples of compounds that give such a structural unit include structural units represented by the following formulae.

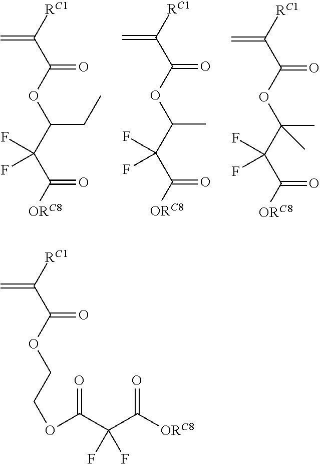

In the above formulae, R^{C1} and R^{C8} are as defined in connection with the above general formula (a1-3).

The compound represented by the above formula, in which R^{C8} represents an acid-dissociable group or an alkali-dissociable group can be synthesized using as a raw material, for example, a compound represented by each formula in which R^{C8} represents a hydrogen atom, or a derivative thereof. Referring to an exemplary compound includes an alkali-dissociable group in which R^{C8} is represented by the above formula (R1-4), this compound can be obtained by allowing, for example, a compound represented by the following general formula (m-2-3) to react with a compound represented by the following formula (m-2-4-3).

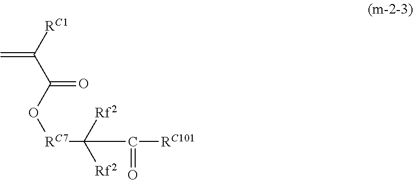

In the above general formula (m-2-3), R^{C1}, R^{C7} and Rf² are as defined in connection with the above general formula (a1-3); and R^{C101} represents a hydroxyl group or a halogen atom.

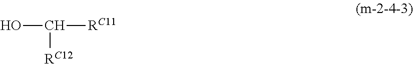

In the above general formula (m-2-4-3), R^{C11} and R^{C12} are as defined in connection with the above general formula (R1-4).

The polymer (C) may have only one type of the above structural units (a1-1) to (a1-3), or two or more thereof, and preferably has at least two types of the structural units (a1-1) to (a1-3) and more preferably has the structural unit (a1-2) and the structural unit (a1-3). Moreover, among the above structural units (a1-1) to (a1-3), including the structural unit (a1-3) is more preferred. It is to be noted that the polymer (C) may have the above structural units (a1-1) to (a1-3) each alone or two or more thereof.

The polymer (C) may further have in addition to the above structural unit (C1): a structural unit that includes an acid-dissociable group other than the structural unit (C1) (hereinafter, may be referred to as “structural unit (C2)”); a structural unit (C3) that includes an alkali-soluble group excluding those corresponding to the above structural unit (C1) (hereinafter, may be merely referred to as “structural unit (C3)”); or a structural unit (C4) that includes a lactone skeleton (hereinafter, may be merely referred to as “structural unit (C4)”). When the polymer (C) has the structural unit (C3) and/or the structural unit (C4), solubility in the developer solution can be improved.

### (Structural Unit (C2))

When a polymer having the structural unit (C2) is used as the polymer (C), use in combination with the polymer (B) is particularly preferred for a positive type radiation-sensitive resin composition. In this case, the difference between an advancing contact angle and a receding contact angle of the resist coating film can be decreased, whereby a scanning speed in liquid immersion lithography can be accelerated. The structural unit (C2) is preferably, for example, a structural unit represented by the above formula (2).

In addition, the structural unit (C2) is particularly preferably a structural unit represented by the following formula (C2-1-1) among the structural units represented by the above formula (2).

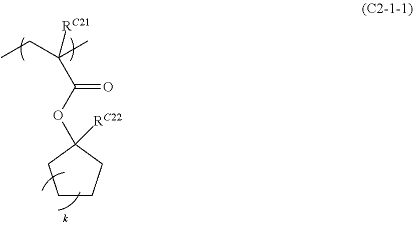

In the above formula (C2-1-1), R^{C21} represents a hydrogen atom or a methyl group; R^{C22} represents a linear or branched alkyl group having 1 to 4 carbon atoms; and k is an integer of 1 to 4.

In the above formula (C2-1-1), examples of the linear or branched alkyl group having 1 to 4 carbon atoms represented by R^{C22} include a methyl group, an ethyl group, a n-propyl group, an i-propyl group, a n-butyl group, a 2-methylpropyl group, a 1-methylpropyl group, a t-butyl group, and the like.

The polymer (C) may have the structural unit (C2) either one type alone or in combination of two or more thereof.

### (Structural Unit (C3))

The alkali-soluble group in the structural unit (C3) is preferably a functional group having a hydrogen atom having a pKa (wherein, Ka is a dissociate constant) of 4 to 11. When the alkali-soluble group is a functional group having a hydrogen atom having a pKa of 4 to 11, solubility in the developer solution can be improved. Specific examples of such a functional group include functional groups represented by the following formula (C3a) and formula (C3b), and the like.

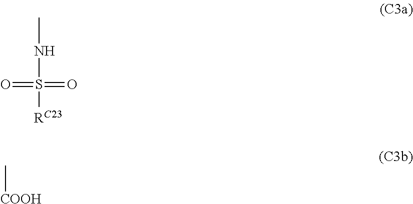

In the above formula (C3a), R^{C23} represents a hydrocarbon group having 1 to 10 carbon atoms substituted with a fluorine atom.

In the above formula (C3a), the hydrocarbon group having 1 to 10 carbon atoms substituted with a fluorine atom represented by R^{C23} is not particularly limited as long as one, or two or more hydrogen atoms in the hydrocarbon group having 1 to 10 carbon atoms is/are substituted by a fluorine atom, and a trifluoromethyl group is preferred.

The main chain skeleton of the structural unit (C3) is not particularly limited, and is preferably a methacrylic acid ester skeleton, an acrylic acid ester skeleton, or an α-trifluoro acrylic acid ester skeleton.

Examples of the structural unit (C3) include structural units derived from compounds represented by the following general formulae (C3a-1) and (C3b-1).

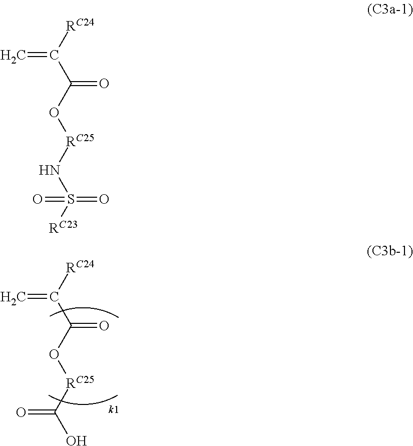

The R^{C24} represents a hydrogen atom, a methyl group, or a trifluoromethyl group; R^{C25} represents a bivalent linking group; R^{C23} represents a hydrocarbon group having 1 to 10 carbon atoms substituted with a fluorine atom; and k1 is 0 or 1.

The bivalent linking group represented by the R^{C25} may be similarly defined to R^{C7} in the above formula (a1-3). In addition, the R^{C23} may be similarly defined in connection with the above formula (C3a).

The polymer (C) may have the structural unit (C3) either alone or in combination of two or more thereof.

### (Structural Unit (C4))

Examples of the structural unit (C4) include structural units exemplified as the structural unit (1-1) in the polymer (B).

### (Proportion of Each Structural Unit Contained)

The proportion of each structural unit contained with respect to 100 mol % in total of the structural units in the polymer (C) is shown below. The proportion of the structural unit (C1) contained is preferably 20 to 90 mol %, and more preferably 20 to 80 mol %. In addition, the proportion of the structural unit (C2) contained is typically no greater than 80 mol %, preferably 20 to 80 mol %, and more preferably 30 to 70 mol %. The proportion of the structural unit (C2) contained falling within this range is particularly preferred in light of a decrease in the difference between the advancing contact angle and the receding contact angle. Furthermore, the proportion of the structural unit (C3) contained is typically no greater than 50 mol %, preferably 5 to 30 mol %, and more preferably 5 to 20 mol %. The proportion of the structural unit (C4) contained is typically no greater than 50 mol %, preferably 5 to 30 mol %, and more preferably 5 to 20 mol %.

The weight average molecular weight of the polymer (C) in terms of a polystyrene equivalent as determined by a gel permeation chromatography (GPC) method (hereinafter, may be referred to as “Mw”) is preferably 1,000 to 50,000, more preferably 1,000 to 40,000, and still more preferably 1,000 to 30,000. When the Mw is less than 1,000, obtaining a resist coating film having a sufficient receding contact angle may fail. On the other hand, when the Mw exceeds 50,000, the developability of the resist coating film may be deteriorated. In addition, a ratio (Mw/Mn) of the Mw to the number average molecular weight in terms of a polystyrene equivalent as determined by a GPC method (hereinafter, may be referred to as “Mn”) of the polymer (C) is preferably 1 to 5, and more preferably 1 to 4.

The content of the polymer (C) is preferably 0.1 to 20 parts by mass, more preferably 1 to 10 parts by mass, and still more preferably 1 to 7.5 parts by mass with respect to 100 parts by mass of the polymer (B). When the content of the polymer (C) is less than 0.1 parts by mass, the effects achieved by including the polymer (C) may not be sufficiently achieved. On the other hand, when the content is greater than 20 parts by mass, water repellency of the surface of the resist coating film may be so great that development defects may occur.

### (Proportion of Fluorine Atoms Contained)

The proportion of the fluorine atoms contained in the polymer (C) is typically no less than 5% by mass, preferably 5 to 50% by mass, and more preferably 5 to 40% by mass. It is to be noted that the proportion of fluorine atoms contained may be determined by ¹³C-NMR. When the proportion of fluorine atoms contained in the polymer (C) falls within the above range, water repellency of the surface of the resist coating film formed from the photoresist composition containing the polymer (C) and the polymer (B) described above can be improved, and thus it is not necessary to separately form an upper layer film in liquid immersion lithography.

### (Synthesis Method of Polymer (C))

The polymer (C) may be synthesized by polymerization of, for example, a polymerizable unsaturated monomer corresponding to each predetermined structural unit, using a radical polymerization initiator such as a hydroperoxide, a dialkylperoxide, a diacylperoxide, an azo compound or the like in a suitable solvent, in the presence of a chain transfer agent if necessary.

Examples of the solvent used in the polymerization include: alkanes such as n-pentane, n-hexane, n-heptane, n-octane, n-nonane and n-decane; cycloalkanes such as cyclohexane, cycloheptane, cyclooctane, decalin and norbornane; aromatic hydrocarbons such as benzene, toluene, xylene, ethylbenzene and cumene; halogenated hydrocarbons such as chlorobutanes, bromohexanes, dichloroethanes, hexamethylenedibromide and chlorobenzene; saturated carboxylate esters such as ethyl acetate, n-butyl acetate, i-butyl acetate and methyl propionate; ketones such as acetone, 2-butanone, 4-methyl-2-pentanone and 2-heptanone; ethers such as tetrahydrofuran, dimethoxyethanes and diethoxyethanes; alcohols such as methanol, ethanol, 1-propanol, 2-propanol and 4-methyl-2-pentanol, and the like. These solvents may be used either alone, or as a mixture of two or more thereof.

The reaction temperature in the polymerization is typically 40 to 150° C., and preferably 50 to 120° C. The reaction time in the polymerization is typically 1 to 48 hrs, and preferably 1 to 24 hrs.

### [(D) Acid Diffusion Control Agent]

The radiation-sensitive resin composition of the embodiment of the present invention preferably contains an acid diffusion control agent that controls a phenomenon of diffusion in the resist coating film of an acid generated from the radiation-sensitive acid generating agent by exposure, thereby inhibiting an undesired chemical reaction in an unexposed area. By containing such an acid diffusion control agent, the radiation-sensitive resin composition can have improved storage stability of the radiation-sensitive resin composition, along with further improvement of resolution. In addition, an alteration of a line width of the resist pattern due to varying post-exposure delay (PED) from the exposure to the development process to be prevented. As a result, the radiation-sensitive resin composition can improve process stability.

Such an acid diffusion control agent is exemplified by those disclosed in PCT International Publication No. 2009/051088, paragraph nos. [0176] to [0187]. In other words, the acid diffusion control agent is preferably a nitrogen-containing organic compound having a basicity that is unchanged in accordance the exposure and/or heat treatment in the step of forming a resist pattern. The nitrogen-containing organic compound is exemplified by compounds represented by the following formula (hereinafter, may be referred to as “nitrogen-containing compound (α)”), diamine compounds having two nitrogen atoms in the same molecule (hereinafter, may be referred to as “nitrogen-containing compound (β)”), polyamino compounds and polymers having at least three nitrogen atoms (hereinafter, may be referred to as “nitrogen-containing compound (γ)”), amide group-containing compounds, urea compounds, nitrogen-containing heterocyclic compounds, and the like.

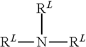

In the above formula, R^{L} each independently represents a hydrogen atom, an alkyl group, an aryl group or an aralkyl group, wherein a part or all of hydrogen atoms that R^{L} has may be substituted.

The alkyl group which may be substituted represented by the R^{L} has, for example, preferably 1 to 15 carbon atoms, and more preferably 1 to 10 carbon atoms. Examples of the alkyl group include a methyl group, an ethyl group, a n-propyl group, an i-propyl group, a n-butyl group, a 2-methylpropyl group, a 1-methylpropyl group, a t-butyl group, a n-pentyl group, a neopentyl group, a n-hexyl group, a n-heptyl group, a n-octyl group, a n-ethylhexyl group, a n-nonyl group, a n-decyl group, a hydroxymethyl group, a 2-hydroxyethyl group, a 3-hydroxypropyl group, and the like.

The aryl group which may be substituted represented by the R^{L} has, for example, 6 to 12 carbon atoms, and specific examples are a phenyl group, an o-tolyl group, a m-tolyl group, a p-tolyl group, a 2,3-xylyl group, a 2,4-xylyl group, a 2,5-xylyl group, a 2,6-xylyl group, a 3,4-xylyl group, a 3,5-xylyl group, a cumenyl group, a 1-naphthyl group, and the like.

The aralkyl group which may be substituted represented by the R^{L} has, for example, preferably 7 to 19 carbon atoms, and more preferably 7 to 13 carbon atoms. Examples of the aralkyl group include a benzyl group, an α-methylbenzyl group, a phenethyl group, a 1-naphthylmethyl group, and the like.

Examples of the nitrogen-containing compound (α) include: monoalkylamines such as n-hexylamine, n-heptylamine, n-octylamine, n-nonylamine and n-decylamine; dialkylamines such as di-n-butylamine, di-n-pentylamine, di-n-hexylamine, di-n-heptylamine, di-n-octylamine, di-n-nonylamine and di-n-decylamine; trialkylamines such as triethylamine, tri-n-propylamine, tri-n-butylamine, tri-n-pentylamine, tri-n-hexylamine, tri-n-heptylamine, tri-n-octylamine, tri-n-nonylamine and tri-n-decylamine; alkanolamines such as ethanolamine, diethanolamine and triethanolamine; aromatic amines such as aniline, N-methylaniline, N,N-dimethyl aniline, 2-methylaniline, 3-methylaniline, 4-methylaniline, 4-nitroaniline, diphenylamine, triphenylamine and 1-naphthylamine, and the like.

Examples of the nitrogen-containing compound (3) include ethylenediamine, N,N,N′,N′-tetramethylethylenediamine, tetramethylenediamine, hexamethylenediamine, N,N,N′,N′-tetrakis(2-hydroxyethyl)ethylenediamine, N,N,N′,N′-tetrakis(2-hydroxypropyl)ethylenediamine, 4,4′-diaminodiphenylmethane, 4,4′-diaminodiphenyl ether, 4,4′-diaminobenzophenone, 4,4′-diaminodiphenylamine, 2,2′-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, and the like.

Examples of the nitrogen-containing compound (γ) include polyethyleneimine, polyallylamine, polymers of N-(2-dimethylaminoethyl)acrylamide, and the like.

Examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tri-n-butylthiourea, and the like.

Examples of the nitrogen-containing heterocyclic compound include: imidazoles such as imidazole, benzimidazole, 2-methylimidazole, 4-methylimidazole, 1,2-dimethyl imidazole, 2-phenylimidazole, 4-phenylimidazole, 4-methyl-2-phenylimidazole and 2-phenylbenzimidazole; pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinic amide, quinoline, 8-oxyquinoline and acridine, as well as pyrazine, pyrazole, pyridazine, quinoxaline, purine, pyrrolidine, piperidine, 1-piperidine ethanol, 2-piperidine ethanol, morpholine, 4-methylmorpholine, piperazine, 1,4-dimethylpiperazine, 1,4-diazabicyclo[2.2.2]octane, and the like.

Also, a compound having an acid-dissociable group may be used as the nitrogen-containing organic compound. Examples of the nitrogen-containing organic compound having an acid-dissociable group include N-(t-butoxycarbonyl)piperidine, N-(t-butoxycarbonyl)imidazole, N-(t-butoxycarbonyl)benzimidazole, N-(t-butoxycarbonyl)-2-phenylbenzimidazole, N-(t-butoxycarbonyl)di-n-octylamine, N-(t-butoxycarbonyl), N-(t-butoxycarbonyl)dicyclohexylamine, N-(t-butoxycarbonyl)diphenylamine, tert-butyl-4-hydroxy-1-piperidine carboxylate, and the like.

Of these nitrogen-containing organic compounds, the nitrogen-containing compound (α), the nitrogen-containing compound (β), the nitrogen-containing heterocyclic compound, the nitrogen-containing organic compound having an acid-dissociable group, and the like are preferred.

Alternatively, a compound represented by the following formula (D1-0) may be also used as the acid diffusion control agent.

X⁺Z⁻ (D1-0)

In the above formula (D1-0), X⁺ represents a cation represented by the following formula (D1-1) or (D1-2); Z⁻ represents OH⁻, an anion represented by the general formula of (D1-3)R^{D1}—COO⁻, or, an anion represented by the general formula of (D1-4)R^{D1}—SO₃⁻, wherein, in the above formula (D1-3) and (D1-4), R^{D1} represents an unsubstituted or optionally substituted alkyl group, alicyclic hydrocarbon group or aryl group.

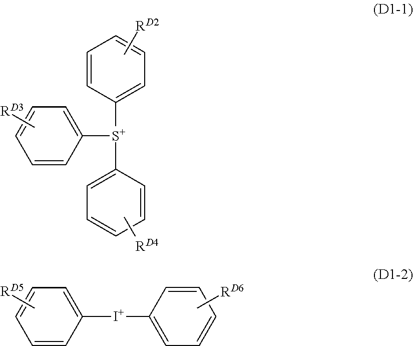

In the above formula (D1-1), R^{D2} to R^{D4} each independently represent a hydrogen atom, an alkyl group, an alkoxyl group, a hydroxyl group, or a halogen atom. In the above formula (D1-2), R^{D5} and R^{D6} each independently represent a hydrogen atom, an alkyl group, an alkoxy group, a hydroxyl group, or a halogen atom.

The compound is used as an acid diffusion control agent that is degraded by exposure and lose acid diffusion controllability (hereinafter, may be also referred to as “photodegradable acid diffusion control agent”). Due to including the compound, an acid is diffused at sites exposed with light whereas diffusion of an acid is controlled at sites not exposed with light, thereby enabling a contrast between the site exposed with light and the site not exposed with light to be enhanced (i.e., achievement of clear boundary between the sites exposed and not exposed with light); therefore, in particular, LWR and MEEF of the radiation-sensitive resin composition can be effectively improved.

### (X⁺)

X⁺ in the above formula (D1-0) is a cation represented by the general formula (D1-1) or (D1-2) as described above. In addition, R^{D2} to R^{D4} in the general formula (D1-1) each independently represent a hydrogen atom, an alkyl group, an alkoxy group, a hydroxyl group, or a halogen atom. Of these, due to having an effect of decreasing the solubility of the compound in the developer solution, R^{D2} to R^{D4} preferably represent a hydrogen atom, an alkyl group, an alkoxy group or a halogen atom. In addition, R^{D5} and R^{D6} in the general formula (D1-2) each independently represent a hydrogen atom, an alkyl group, an alkoxy group, a hydroxyl group, or a halogen atom. Of these, a hydrogen atom, an alkyl group and a halogen atom are preferred.

### (Z⁻)

Z⁻ in the above formula (D1-0) is OH⁻, an anion represented by the general formula (D1-3)R^{D1}—COO⁻, or an anion represented by the general formula (D1-4)R^{D1}—SO₃⁻ as described above, wherein, R^{D1} in the general formulae (D1-3) and (D1-4) is an unsubstituted or optionally substituted alkyl group, alicyclic hydrocarbon group or aryl group, and of these, an alicyclic hydrocarbon group or an aryl group is preferred due to having an effect of decreasing the solubility of the compound in the developer solution.

Examples of the optionally substituted alkyl group include groups having one or more substituent such as e.g.: hydroxyalkyl groups having 1 to 4 carbon atoms such as a hydroxymethyl group, a 1-hydroxyethyl group, a 2-hydroxyethyl group, a 1-hydroxypropyl group, a 2-hydroxypropyl group, a 3-hydroxypropyl group, a 1-hydroxybutyl group, a 2-hydroxybutyl group, a 3-hydroxybutyl group and a 4-hydroxybutyl group; alkoxy groups having 1 to 4 carbon atoms such as a methoxy group, an ethoxy group, a n-propoxy group, an i-propoxy group, a n-butoxy group, a 2-methylpropoxy group, a 1-methylpropoxy group and a t-butoxy group; a cyano group; cyanoalkyl groups having 2 to 5 carbon atoms such as a cyanomethyl group, a 2-cyanoethyl group, a 3-cyanopropyl group and a 4-cyanobutyl group, and the like. Of these, a hydroxymethyl group, a cyano group and a cyanomethyl group are preferred.

Examples of the optionally substituted alicyclic hydrocarbon group include cycloalkane skeletons such as hydroxycyclopentane, hydroxycyclohexane and cyclohexanone; monovalent groups derived from an alicyclic hydrocarbon having a bridged alicyclic skeleton such as 1,7,7-trimethylbicyclo[2.2.1]heptan-2-one (camphor), and the like. Of these, groups derived from 1,7,7-trimethyl bicyclo[2.2.1]heptan-2-one are preferred.

Examples of the optionally substituted aryl group include groups obtained by substituting a part or all of hydrogen atoms included in an aryl group such as a phenyl group, a benzyl group, a phenylethyl group, a phenylpropyl group or a phenylcyclohexyl group with a hydroxyl group, a cyano group, etc., and the like. Of these, groups obtained by substituting a part or all of hydrogen atoms included in a phenyl group, a benzyl group or a phenylcyclohexyl group with a hydroxyl group, a cyano group, etc., are preferred.

It is to be noted that Z⁻ in the general formula (D1-0) is preferably an anion represented by the following formula (1a) (i.e., an anion represented by the general formula (D1-3) in which R^{D1} represents a 2-hydroxyphenyl group) or an anion represented by the following formula (1b) (i.e., an anion represented by the general formula (D1-4) in which R^{D}′ represents a group derived from 1,7,7-trimethyl bicyclo[2.2.1]heptan-2-one).

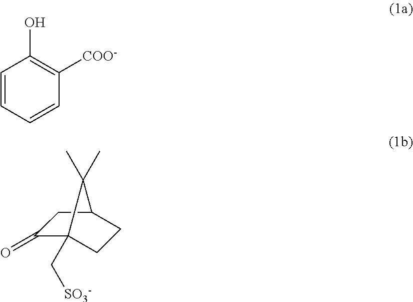

The photodegradable acid diffusion control agent is a compound represented by the above general formula (D1-0), and specifically, a sulfonium salt compound or an iodonium salt compound that satisfies the aforementioned requirements.

Examples of the sulfonium salt compound include triphenylsulfonium hydroxide, triphenylsulfonium acetate, triphenylsulfonium salicylate, diphenyl-4-hydroxyphenylsulfonium hydroxide, diphenyl-4-hydroxyphenylsulfonium acetate, diphenyl-4-hydroxyphenylsulfonium salicylate, triphenylsulfonium 10-camphorsulfonate, 4-t-butoxyphenyldiphenylsulfonium 10-camphorsulfonate, and the like. It is to be noted that these sulfonium salt compounds may be used either alone or in combination of two or more thereof.

Moreover, examples of the iodonium salt compound include bis(4-t-butylphenyl)iodonium hydroxide, bis(4-t-butylphenyl)iodonium acetate, bis(4-t-butylphenyl)iodonium hydroxide, bis(4-t-butylphenyl)iodonium acetate, bis(4-t-butylphenyl)iodonium salicylate, 4-t-butylphenyl-4-hydroxyphenyliodonium hydroxide, 4-t-butylphenyl-4-hydroxyphenyliodonium acetate, 4-t-butylphenyl-4-hydroxyphenyliodonium salicylate, bis(4-t-butylphenyl)iodonium 10-camphorsulfonate, diphenyliodonium 10-camphorsulfonate, and the like. It is to be noted that iodonium salt compounds may be used either alone or in combination of two or more thereof.

The acid diffusion control agent may be used either alone, or as a mixture of two or more thereof.

The amount of the acid diffusion control agent (D) blended is preferably 0.1 parts by mass to 25 parts by mass, more preferably 1 parts by mass to 20 parts by mass, and still more preferably 3 parts by mass to 16 parts by mass with respect to 100 parts by mass of the polymer (B). In this case, when the amount of the acid diffusion control agent blended is no less than 0.1 parts by mass, deterioration of the pattern configuration and/or dimension fidelity depending on the process conditions can be inhibited, whereas when the amount is no greater than 25 parts by mass, the sensitivity and/or alkali developability as a resist can be further improved.

### [(E) Lactone Compound]

The lactone compound (E) has an effect of efficiently segregating the polymer (C) on the surface of the resist coating film, the polymer (C) having an action of allowing water repellency to be expressed on the surface of the resist coating film in liquid immersion lithography. Thus, due to including the lactone compound (E) when the polymer (C) is used, the amount of the polymer (C) added can be reduced. Therefore, elution of a component from a resist coating film to a liquid for liquid immersion lithography can be inhibited without impairing basic characteristics as a resist, and water repellency of the surface of the resist coating film that inhibits defects derived from the liquid for liquid immersion lithography such as watermark defects can be maintained as a result of no remaining of droplets even if liquid immersion lithography is carried out by high-speed scanning.

Specific examples of the lactone compound (E) include γ-butyrolactone, valerolactone, mevalonic lactone, norbornanelactone, and the like. Of these, γ-butyrolactone is preferred.

The radiation-sensitive resin composition may contain the lactone compound (E) of only one type, or two or more types thereof.

The content of the lactone compound (E) in the radiation-sensitive resin composition is typically 30 to 500 parts by mass, and preferably 30 to 300 parts by mass with respect to 100 parts by mass of the polymer (B). When the content of the lactone compound (E) is too small, water repellency of the surface of the resist coating film cannot be sufficiently attained in adding a small amount of the polymer (C). On the other hand, when the content is excessive, basic performances of the resist and pattern configuration after the development may be significantly deteriorated.

### [Other Additives]

To the radiation-sensitive resin composition of the embodiment of the present invention may be added other component(s) in addition to the components (A) to (E). The other component is exemplified by other radiation-sensitive compound, a dissolution enhancing agent, a surfactant, a sensitizing agent, and the like.

### [Other Radiation-Sensitive Compound]

In the radiation-sensitive resin composition of the embodiment of the present invention, at least one compound other than the compound (A) (hereinafter, may be referred to as “other radiation-sensitive compound”) may be used in combination as a radiation-sensitive compound (radiation-sensitive acid generating agent).

Examples of the other radiation-sensitive compound include onium salt compounds, sulfone compounds, sulfonic acid esterified products, sulfonimide compounds, diazomethane compounds, disulfonylmethane compounds, oximesulfonate compounds, hydrazine sulfonate compounds, and the like.

These compounds are exemplified by compounds described in PCT International Publication No. 2009/051088, paragraph nos. [0086] to [0113].

Of these other radiation-sensitive compounds, one, or two or more compounds selected from the group consisting of an onium salt compound, a sulfonimide compound and a diazomethane compound are preferred.

Examples of particularly preferable other radiation-sensitive compound include diphenyliodonium trifluoromethanesulfonate, diphenyliodonium nonafluoro-n-butanesulfonate, diphenyliodonium p-toluenesulfonate, diphenyliodonium 10-camphorsulfonate, diphenyliodonium 2-trifluoromethylbenzenesulfonate, diphenyliodonium 4-trifluoromethylbenzenesulfonate, diphenyliodonium 2,4-difluorobenzenesulfonate, diphenyliodonium 1,1,2,2-tetrafluoro-2-(norbornan-2-yl)ethanesulfonate, diphenyliodonium 2-(5-t-butoxycarbonyloxybicyclo[2.2.1]heptan-2-yl)-1,1,2,2-tetrafluoroethanesulfonate, diphenyliodonium 2-(6-t-butoxycarbonyloxybicyclo[2.2.1]heptan-2-yl)-1,1,2,2-tetrafluoroethanesulfonate, diphenyliodonium 1,1-difluoro-2-(bicyclo[2.2.1]heptan-2-yl)ethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium p-toluenesulfonate, bis(4-t-butylphenyl)iodonium 10-camphorsulfonate, bis(4-t-butylphenyl)iodonium 2-trifluoromethylbenzenesulfonate, bis(4-t-butylphenyl)iodonium 4-trifluoromethylbenzenesulfonate, bis(4-t-butylphenyl)iodonium 2,4-difluorobenzenesulfonate, bis(4-t-butylphenyl)iodonium 1,1,2,2-tetrafluoro-2-(norbornan-2-yl)ethanesulfonate, bis(4-t-butylphenyl)iodonium 1,1-difluoro-2-(bicyclo[2.2.1]heptan-2-yl)ethanesulfonate,

triphenylsulfonium trifluoromethanesulfonate, triphenylsulfonium nonafluoro-n-butanesulfonate, triphenylsulfonium p-toluenesulfonate, triphenylsulfonium 10-camphorsulfonate, triphenylsulfonium 2-trifluoromethylbenzenesulfonate, triphenylsulfonium 4-trifluoromethylbenzenesulfonate, triphenylsulfonium 2,4-difluorobenzenesulfonate, triphenylsulfonium 1,1,2,2-tetrafluoro-2-(norbornan-2-yl)ethanesulfonate, triphenylsulfonium 2-(5-t-butoxycarbonyloxybicyclo[2.2.1]heptan-2-yl)-1,1,2,2-tetrafluoroethanesulfonate, triphenylsulfonium 2-(6-t-butoxycarbonyloxybicyclo[2.2.1]heptan-2-yl)-1,1,2,2-tetrafluoroethanesulfonate, triphenylsulfonium 2-(5-pivaloyloxybicyclo[2.2.1]heptan-2-yl)-1,1,2,2-tetrafluoroethanesulfonate, triphenylsulfonium 2-(6-pivaloyloxybicyclo[2.2.1]heptan-2-yl)-1,1,2,2-tetrafluoroethanesulfonate, triphenylsulfonium 2-(5-hydroxybicyclo[2.2.1]heptan-2-yl)-1,1,2,2-tetrafluoroethanesulfonate, triphenylsulfonium 2-(6-hydroxybicyclo[2.2.1]heptan-2-yl)-1,1,2,2-tetrafluoroethanesulfonate,

triphenylsulfonium 2-(5-methanesulfonyloxybicyclo[2.2.1]heptan-2-yl)-1,1,2,2-tetrafluoroethanesulfonate, triphenylsulfonium 2-(6-methanesulfonyloxybicyclo[2.2.1]heptan-2-yl)-1,1,2,2-tetrafluoroethanesulfonate, triphenylsulfonium 2-(5-i-propanesulfonyloxybicyclo[2.2.1]heptan-2-yl)-1,1,2,2-tetrafluoroethanesulfonate, triphenylsulfonium 2-(6-i-propanesulfonyloxybicyclo[2.2.1]heptan-2-yl)-1,1,2,2-tetrafluoroethanesulfonate, triphenylsulfonium 2-(5-n-hexanesulfonyloxybicyclo[2.2.1]heptan-2-yl)-1,1,2,2-tetrafluoroethanesulfonate, triphenylsulfonium 2-(6-n-hexanesulfonyloxybicyclo[2.2.1]heptan-2-yl)-1,1,2,2-tetrafluoroethanesulfonate, triphenylsulfonium 2-(5-oxobicyclo[2.2.1]heptan-2-yl)-1,1,2,2-tetrafluoroethanesulfonate, triphenylsulfonium 2-(6-oxobicyclo[2.2.1]heptan-2-yl)-1,1,2,2-tetrafluoroethanesulfonate, triphenylsulfonium 1,1-difluoro-2-(bicyclo[2.2.1]heptan-2-yl)ethanesulfonate,

1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium 1,1,2,2-tetrafluoro-2-(norbornan-2-yl)ethanesulfonate, 1-(4-n-butoxynaphthalen-1-yl)tetrahydrothiophenium 2-(5-t-butoxycarbonyloxybicyclo[2.2.1]heptan-2-yl)-1,1,2,2-tetrafluoroethanesulfonate, 1-(4-n-butoxynaphthalen-1-yl)tetrahydrothiophenium 2-(6-t-butoxycarbonyloxybicyclo[2.2.1]heptan-2-yl)-1,1,2,2-tetrafluoroethanesulfonate, 1-(4-n-butoxynaphthalen-1-yl)tetrahydrothiophenium 1,1-difluoro-2-(bicyclo[2.2.1]heptan-2-yl)ethanesulfonate,

N-(trifluoromethanesulfonyloxy)succinimide, N-(10-camphorsulfonyloxy)succinimide, N-[(5-methyl-5-carboxymethylbicyclo[2.2.1]heptan-2-yl)sulfonyloxy]succinimide, N-(trifluoromethanesulfonyloxy)bicyclo[2.2.1]hept-5-ene-2,3-dicarboxylmide, N-(nonafluoro-n-butanesulfonyloxy)bicyclo[2.2.1]hept-5-ene-2,3-dicarboxylmide, N-[1,1,2,2-tetrafluoro-2-(norbornan-2-yl)ethanesulfonyloxy]bicyclo[2.2.1]hept-5-ene-2,3-dicarboxylmide, N-(10-camphorsulfonyloxy)bicyclo[2.2.1]hept-5-ene-2,3-dicarboxylmide, N-[2-(5-oxobicyclo[2.2.1]heptan-2-yl)-1,1,2,2-tetrafluoroethanesulfonyloxy]bicyclo[2.2.1]hept-5-ene-2,3-dicarboxylmide, N-[2-(6-oxobicyclo[2.2.1]heptan-2-yl)-1,1,2,2-tetrafluoroethanesulfonyloxy]bicyclo[2.2.1]hept-5-ene-2,3-dicarboxylmide, N-[1,1-difluoro-2-(bicyclo[2.2.1]heptan-2-yl)ethanesulfonyloxy]bicyclo[2.2.1]hept-5-ene-2,3-dicarboxylmide, bis(cyclohexanesulfonyl)diazomethane, bis(t-butylsulfonyl)diazomethane, bis(1,4-dioxaspiro[4.5]decane-7-sulfonyl)diazomethane, and the like.

The proportion of the other radiation-sensitive compound used may be appropriately selected in accordance with the type of the other radiation-sensitive compound, and is typically no greater than 95 parts by mass, preferably no greater than 90 parts by mass, and more preferably no greater than 80 parts by mass with respect to 100 parts by mass of the total of the compound (A) and the other radiation-sensitive compound. In this case, when the proportion of the other radiation-sensitive compound used is excessive, desired effects of the present invention may be impaired.

### [Dissolution Enhancing Agent]

The radiation-sensitive resin composition may contain a dissolution enhancing agent having a property that solubility in an alkaline developer is enhanced by an action of an acid.

Such a dissolution enhancing agent is exemplified by a compound having an acidic functional group such as a phenolic hydroxyl group, a carboxy group or a sulfonic acid group, as well as a compound obtained by substituting a hydrogen atom of the acidic functional group in the above-described compound with an acid-dissociable group, and the like.

The dissolution enhancing agent may be either a low molecular compound or a high molecular compound, and as a high molecular dissolution enhancing agent in a radiation-sensitive negative type resin composition, for example, an acid-dissociable group-containing polymer in the positive type radiation-sensitive resin composition may be used. The dissolution enhancing agent may be used either alone, or as a mixture of two or more thereof.

The content of the dissolution enhancing agent is typically no greater than 50 parts by mass, and preferably no greater than 20 parts by mass with respect to 100 parts by mass of the component of the polymer (B).

### [Surfactant]

The radiation-sensitive resin composition may contain a surfactant having an effect of improving coating properties, striation, developability and the like of the radiation-sensitive resin composition.

As such a surfactant, any of an anionic, cationic, nonionic or amphoteric surfactant may be used, and a nonionic surfactant is preferably used.

Examples of the nonionic surfactant include polyoxyethylene higher alkyl ethers, polyoxyethylene higher alkylphenyl ethers, higher aliphatic acid diesters of polyethylene glycol, as well as each series of the following trade names, “KP” (manufactured by Shin-Etsu Chemical Co., Ltd.), “Polyflow” (manufactured by Kyoeisha Chemical Co., Ltd.), “EFTOP” (manufactured by Mitsubishi Materials Electronic Chemicals Co., Ltd. (formerly, JEMCO Inc.)), “MEGAFACE” (manufactured by Dainippon Ink and Chemicals, Incorporated), “Fluorad” (manufactured by Sumitomo 3M Limited), “AsahiGuard” and “Surflon” (manufactured by Asahi Glass Co., Ltd.), and the like. The surfactant may be used either alone, or as a mixture of two or more thereof.

The content of the surfactant is typically no greater than 2 parts by mass, and preferably no greater than 1.5 parts by mass with respect to 100 parts by mass of the component of the polymer (B) as the active ingredient of the surfactant.

### [Sensitizing Agent]

The radiation-sensitive resin composition may contain a sensitizing agent capable of absorbing energy of a radioactive ray, and transmitting the energy to a radiation-sensitive acid generator, thereby increasing the amount of the acid produced to improve apparent sensitivity of the radiation-sensitive resin composition. Such a sensitizer is exemplified by acetophenones, benzophenones, naphthalenes, biacetyl, eosine, rose bengal, pyrenes, anthracenes, phenothiazines, and the like. These sensitizing agents may be used either alone, or as a mixture of two or more thereof.

The content of the sensitizing agent is typically no greater than 50 parts by mass, and preferably no greater than 30 parts by mass with respect to 100 parts by mass of the component of the polymer (B).

Furthermore, the radiation-sensitive resin composition may contain additives other than those described in the foregoing such as, for example, a dye, a pigment, an adhesion promoter, a halation inhibitor, a storage stabilizer, a defoaming agent and a shape improving agent, specifically 4-hydroxy-4′-methylchalcone, or the like as needed within the range not to impair the effects of the present invention. In this case, due to containing a dye or a pigment, a latent image of the light-exposed site can be visualized to mitigate the influences from halation in the exposure. Moreover, due to containing an adhesion promoter, adhesiveness to the substrate can be improved.

### [Preparation Method of Radiation-Sensitive Resin Composition]

The radiation-sensitive resin composition is prepared in the form of a composition solution by generally dissolving each component in a solvent in use to give a homogenous solution, and thereafter filtering through, for example, a filter having a pore size of about 0.2 μm or the like as needed.

The solvent is exemplified by ethers, esters, ether esters, ketones, ketone esters, amides, amide esters, lactams, (halogenated) hydrocarbons, and the like. More specifically, examples of the solvent include ethylene glycol monoalkyl ethers, diethylene glycol dialkyl ethers, propylene glycol monoalkyl ethers, propylene glycol dialkyl ethers, ethylene glycol monoalkyl ether acetates, propylene glycol monoalkyl ether acetates, acyclic or cyclic ketones, ester acetates, hydroxy ester acetates, alkoxy ester acetates, aceto ester acetates, propionic acid esters, lactic acid esters, other substituted propionic acid esters, (substituted) butyric acid esters, pyruvic acid esters, N,N-dialkylformamides, N,N-dialkylacetamides, N-alkylpyrrolidones, (halogenated) aliphatic hydrocarbons, (halogenated) aromatic hydrocarbons, and the like.

Specific examples of the solvent include solvents described in PCT International Publication No. 2009/051088, paragraph no. [0202].

Of these solvents, propylene glycol monoalkyl ether acetates, acyclic or cyclic ketones, lactic acid esters, 3-alkoxypropionic acid esters and the like are preferred in that favorable film intra-plane uniformity can be secured in coating. Of these, propylene glycol monoalkyl ether acetates and cyclic ketones are more preferred. The solvent may be used either alone, or as a mixture of two or more thereof.

In addition, other solvent may be used as needed together with the solvent described above, such as a solvent having a high boiling point like e.g., benzylethyl ether, di-n-hexyl ether, diethylene glycol monomethyl ether, diethylene glycol monoethyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, ethylene carbonate, propylene carbonate, ethylene glycol monophenyl ether acetate, or the like.

The other solvent may be used either alone, or as a mixture of two or more thereof. The content of the other solvent is typically no greater than 50% by mass, and preferably no greater than 30% by mass with respect to the total of the solvent.

The total content of the solvent is an amount that makes the total solid content of the radiation-sensitive composition solution be typically 5 to 50% by mass, preferably 10 to 50% by mass, more preferably 10 to 40% by mass, still more preferably 10 to 30% by mass, and particularly preferably 10 to 25% by mass. When the total solid content of the solution falls within the above range, favorable film intra-plane uniformity can be secured in coating.

### [Formation of Resist Pattern]

When a resist pattern is formed from the radiation-sensitive resin composition of the embodiment of the present invention, the radiation-sensitive resin composition prepared as described above is applied on a substrate such as, for example, a silicon wafer or a wafer covered with aluminum by an appropriate coating means such as spin-coating, cast coating or roll coating to form a resist coating film. Thereafter, after a heating treatment (hereinafter, may be referred to as “PB”) is carried out beforehand as the case may be, the resist coating film is exposed through a predetermined mask pattern.

The radioactive ray which may be used in the exposure is exemplified by far ultraviolet rays such as a bright line spectrum in a mercury lamp (wavelength: 254 nm), a KrF excimer laser beam (wavelength: 248 nm), an ArF excimer laser beam (wavelength: 193 nm), an F₂ excimer laser beam (wavelength: 157 nm), and EUV light (wavelength: 13 nm, etc.), as well as X-rays such as synchrotron radioactive rays, charged particle-rays such as electron beams, and the like. The radioactive ray is preferably a far ultraviolet ray and a charged particle-ray. More preferably, the radioactive ray is a KrF excimer laser beam (wavelength: 248 nm), an ArF excimer laser beam (wavelength: 193 nm), an F₂ excimer laser beam (wavelength: 157 nm) and electron beams, in accordance with the type of the radiation-sensitive acid generating agent employed. Alternatively, a liquid for liquid immersion lithography may be placed on a resist coating film, and the resist coating film can be exposed through the liquid for liquid immersion lithography (liquid immersion lithography).

In addition, conditions for exposure such as radiation dose may be determined ad libitum depending on the compositional formulation of the radiation-sensitive resin composition, the type of the additive, and the like. Additionally, in forming the resist pattern, it is preferable to carry out a heat treatment after the exposure (hereinafter, may be referred to as “PEB”) in light of improvement of apparent sensitivity of the resist. Heating conditions of the PEB may vary depending on the compositional formulation of the radiation-sensitive resin composition, the type of the additive, and the like, the temperature is typically 30 to 200° C., and preferably 50 to 150° C.

Thereafter, the exposed resist coating film is developed with a developer solution to form a predetermined resist pattern. In general, the radiation-sensitive resin composition enables a positive type pattern to be formed by developing with an alkaline developer, and enables a negative type pattern to be formed by developing with an organic solvent developer solution.

### EXAMPLES

Hereinafter, the present invention will be specifically explained by way of Examples, but the present invention is not limited to these Examples. It is to be noted that the “%” in Examples and Comparative Examples is on molar basis unless otherwise stated particularly. Furthermore, methods for the determination of various types of physical property values, and evaluation methods of various characteristics are shown below.

### [Evaluation Conditions]

With regard to Examples and Comparative Examples, resist patterns were formed according to (P-1) Formation of Positive Type Resist Pattern or (P-2) Formation of Negative Type Resist Pattern described below, and evaluations were made.

### (P-1) Formation of Positive Type Resist Pattern

On a silicon wafer having a diameter of 12 inch on which an underlayer antireflective film having a film thickness of 105 nm had been formed (ARC66, Nissan Chemical Industries, Ltd.), a resist coating film having a film thickness of 75 nm was formed with a radiation-sensitive resin composition, and PB was carried out at 120° C. for 60 sec. Next, the resist coating film was exposed using an ArF excimer laser Immersion Scanner (NSR S610C, NIKON Corporation) through a mask pattern for forming a pattern with a line of 46 nm and a pitch of 92 nm under a condition including NA of 1.3, a ratio of 0.800, and Annular. After the exposure, post-baking (PEB) was carried out on each radiation-sensitive resin composition at a temperature shown in Table 2. Thereafter, a positive type resist pattern was formed by development with a 2.38% by mass aqueous tetramethylammoniumhydroxide solution, washing with water, and drying. According to this procedure, an exposure dose at which a portion exposed through the mask pattern for forming a pattern formed a line having a line width of 46 nm was defined as an optimum exposure dose (Eop).

### [LWR]

The line having a line width of 46 nm formed at the Eop was observed from above the pattern using a line-width measurement SEM “CG4000” of Hitachi High-Technologies Corporation to determine the line width at ten arbitrary points. A value of 3-Sigma (variance) of the measurement of the line width was defined as LWR (nm). When the LWR was no greater than 7.0 nm, the formed pattern configuration was evaluated as being favorable.

### [MEEF]

An LS pattern having a pitch of 92 nm was formed at the Eop using each mask pattern with a target size of the line width of 43 nm, 44 nm, 45 nm, 46 nm, 47 nm, 48 nm or 49 nm with a pitch of 92 nm, and the line width formed on the resist coating film was measured with an SEM for line-width measurement (CG4000, manufactured by Hitachi High-Technologies Corporation). In this procedure, the line width (nm) formed on the resist coating film using each mask pattern was plotted along the ordinate with respect to the target size (nm) along the abscissa, and the slope of the resulting straight line was determined as MEEF performance. The MEEF value more approximate to 1 indicates more favorable mask reproducibility, and the smaller MEEF value indicates a possibility of reducing the cost for producing the mask.

### [Development Defect Inhibitory Ability]

First, on a silicon wafer having a diameter of 12 inch on which an underlayer antireflective film having a film thickness of 105 nm had been formed (“ARC66”, manufactured by Nissan Chemical Industries, Ltd.), a resist coating film having a film thickness of 75 nm was formed with each radiation-sensitive resin composition, and PB was carried out at 120° C. for 60 sec. Next, the resist coating film was exposed using an ArF excimer laser Immersion Scanner (“NSR S610C”, manufactured by NIKON Corporation) through a mask pattern under a condition including NA of 1.3, and Crosspole. After the exposure, post-baking (PEB) was carried out at 105° C. for 60 sec. Thereafter, a positive type resist pattern was formed by development with a 2.38% by mass aqueous tetramethylammoniumhydroxide solution, washing with water, and drying. According to this procedure, an exposure dose at which line-and-space with a width of 45 nm was formed was defined as an optimum exposure dose. Line-and-space with a line width of 45 nm was formed on the entire face of the wafer at the optimum exposure dose, whereby a wafer for inspection of defects was provided. It is to be noted that a scanning electron microscope (“CG4000”, manufactured by Hitachi High-Technologies Corporation) was used for the line-width measurement.

Thereafter, number of defects on the defection inspection wafer was measured using “KLA2810” manufactured by KLA-Tencor Corporation. Moreover, the defects determined with “KLA2810” were classified into those decided to be derived from the resist film, and from foreign substances. After the classification, the total of number decided to be derived from the resist film (number of defects) was calculated in terms of number of defects per 1 cm² of the resist film (defects/cm²). With respect to the development defect inhibitory ability, evaluation was made as being: “favorable (A)” when the number of defects was no greater than 10 defects/cm²; and “unfavorable (B)” when the number was greater than 10 defects/cm².

### (P-2) Formation of Negative Type Resist Pattern

Using a silicon wafer on which an underlayer antireflective film of ARC66 (BREWER SCIENCE, Inc.) having a film thickness of 105 nm had been formed as a substrate, each photoresist composition was applied on the substrate using CLEAN TRACK ACT12 (Tokyo Electron Limited) by spin coating, and PB was carried out on a hot plate at 120° C. for 60 sec to form a resist coating film having a film thickness of 100 nm. The formed resist coating film was subjected to reduction projection exposure using an ArF Immersion Scanner (S610C, Nikon Corporation, numerical aperture: 1.30) through a mask pattern with a dot of 216 nm and a pitch of 416 nm, and through water as a liquid for liquid immersion lithography. Then, PEB was carried out at a temperature (° C.) shown in Table 3 for 60 sec, followed by development using a developer solution shown in Table 3 at 23° C. for 30 sec. Subsequently, a rinse treatment was carried out with 4-methyl-2-pentanol for 10 sec, followed by drying to form a negative type resist pattern. It is to be noted that an exposure dose at which a hole pattern having a diameter of 55 nm was formed on the wafer after the reduction projection was defined as an optimum exposure dose (Eop).

[CDU (nm)]

A hole pattern having a diameter of 55 nm formed on the resist coating film on the substrate at the Eop was observed rom above the pattern using a line-width measurement SEM (CG4000, manufactured by Hitachi High-Technologies Corporation). The diameter was measured at an arbitrary point, and variance of the measurement was evaluated in terms of a 3-Sigma level. When the value of 3-Sigma of the measurement in this procedure was no greater than 3 nm, CDU was evaluated as being favorable, and when the value was beyond 3 nm, CDU was evaluated as being unfavorable.

### [MEEF]

A hole pattern was formed having pitch of 110 nm using a mask pattern with a target size of the hole pattern after the reduction projection exposure of 51 nm, 53 nm, 55 nm, 57 nm or 59 nm at the Eop. In this procedure, the hole width (nm) formed in the resist coating film using each mask pattern was plotted along the ordinate with respect to the hole size (nm) of the mask along the abscissa, and the slope of the line was calculated to determine MEEF. The MEEF value (slope of the line) more approximate to 1 was decided to indicate that the mask reproducibility was favorable.

### Synthesis of Polymer (B) and Polymer (C)

Compounds (M-1) to (M-16) used for synthesizing the polymer (B) and the polymer (C) are shown below.

### Synthesis of Polymer (B)

### Synthesis Example 1

### Synthesis of Polymer (B-1)

A monomer solution was prepared by dissolving 258.5 g (50 mol %) of compound (M-1) described below and 341.5 g (50 mol %) of compound (M-5) described below in 1,200 g of 2-butanone, to which 50.47 g of 2,2′-azobis(2-methylpropionitrile) was further charged. A 3,000 mL three-neck flask charged with 600 g of 2-butanone was purged with nitrogen for 30 min. After the nitrogen purge, the reaction vessel was heated to 80° C. while stirring, and the monomer solution prepared beforehand was added dropwise thereto using a dripping funnel over 3 hrs. A time point at which the dropwise addition was started was defined as a polymerization starting time, and a polymerization reaction was carried out for 6 hrs. After completing the polymerization, the polymerization solution was cooled to no higher than 30° C. by water-cooling, and charged in a mix liquid of methanol and ultra pure water (methanol/ultra pure water=9,600 g/2,400 g). The white powder thus precipitated was filtered off. The white powder obtained by filtration was dispersed in 2,400 g of methanol to give a slurry state, followed by washing and filtration. Such an operation was repeated twice, and thereafter vacuum dried at 50° C. for 17 hrs to obtain a copolymer as a white powder. The copolymer had an Mw of 5,400, Mw/Mn of 1.40, and as a result of a ¹³C-NMR analysis, had the content of each of the structure units derived from the compound (M-1) and the compound (M-5) of 49.5:50.5 (mol %). The copolymer is designated as polymer (B-1).

### Synthesis Examples 2 to 14

### Synthesis of Polymers (B-2) to (B-12) and Polymers (b-1) to (b-2)

Polymers (B-2) to (B-12) and polymers (b-1) to (b-2) were synthesized by a similar operation to Synthesis Example 1 except that the compound of the type at the blend proportion shown in Table 1 was employed.

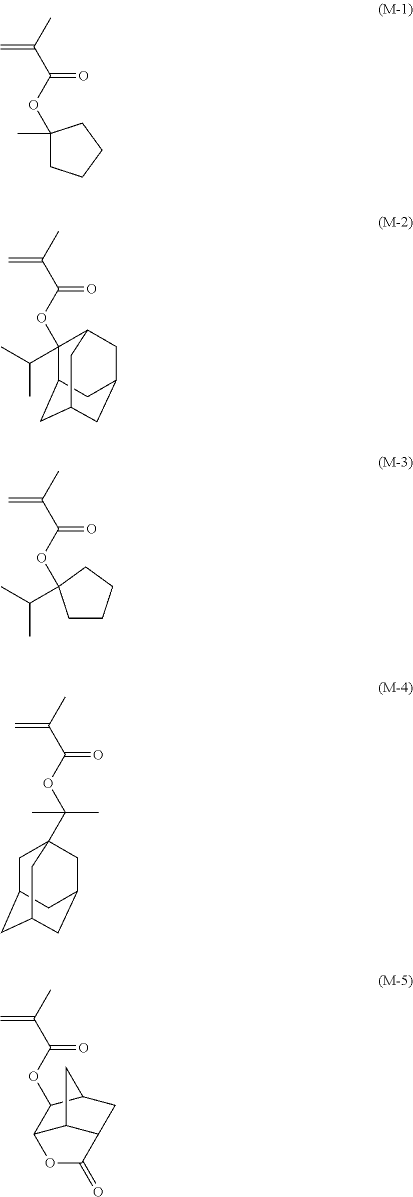

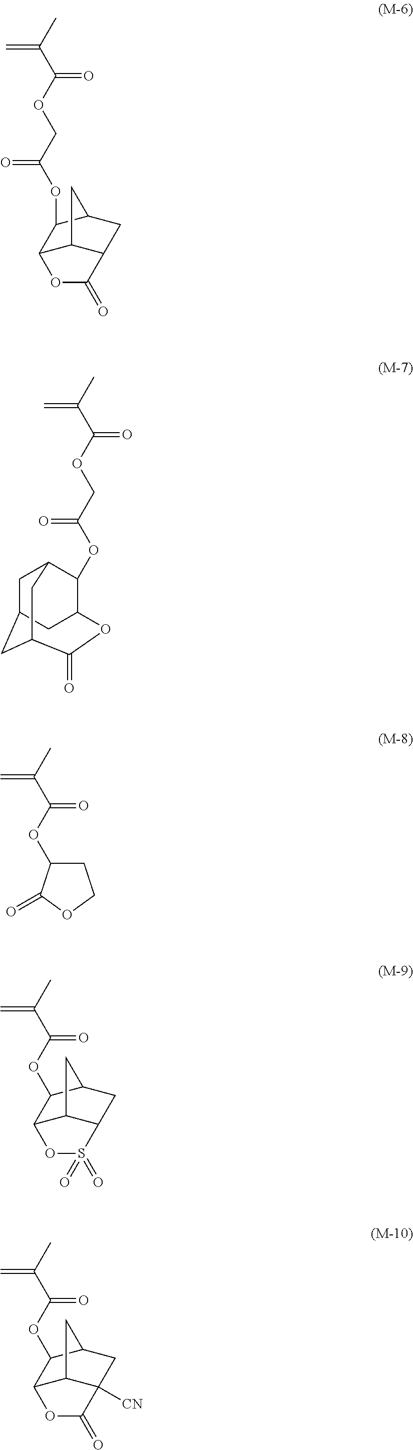 [SMILES: C=C(C)C(=O)OCC(=O)OC1C2CC3C(=O)OC1C3C2 ; C=C(C)C(=O)OCC(=O)OC1C2CC3CC(C2)C(=O)OC1C3 ; C=C(C)C(=O)OC1CCOC1=O ; C=C(C)C(=O)OC1C2CC3C1OS(=O)(=O)C3C2 ; C=C(C)C(=O)OC1C2CC3C1OC(=O)C3(C#N)C2]

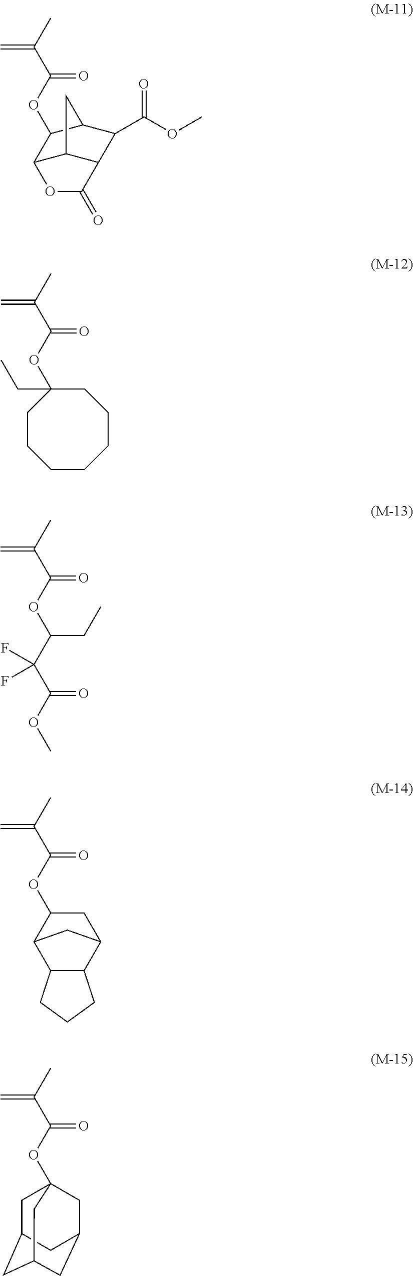

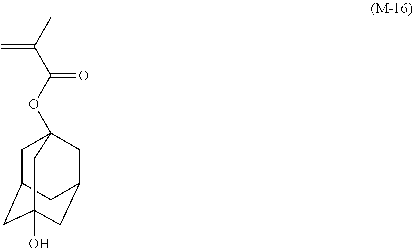 [SMILES: C=C(C)C(=O)OC12CC3CC(CC(O)(C3)C1)C2]

TABLE 1

| | | Compound blend proportion (mol %) | | | | | | | | | | |
|---|---|---|---|---|---|---|---|---|---|---|---|---|
| | | | | | | Compound that | | Content of each structural | | | | |
| | | Compound that gives | | Compound that gives | | gives other | | unit (mol %) | | | | |
| | | structural unit (1) | | structural unit (2) | | structural unit | | Structural | Structural | Other | Physical | |
| | (B) | | blend | | blend | | blend | unit | unit | structural | property value | |
| | Polymer | type | proportion | type | proportion | type | proportion | (1) | (2) | unit | Mw | Mw/Mn |
| Synthesis | B-1 | M-5 | 50 | M-1 | 50 | — | — | 50.5 | 49.5 | — | 5,400 | 1.40 |
| Example 1 | | | | | | | | | | | | |
| Synthesis | B-2 | M-5 | 45 | M-1/M-2 | 45/10 | — | — | 48.1 | 43.2/8.7 | — | 4,100 | 1.38 |
| Example 2 | | | | | | | | | | | | |
| Synthesis | B-3 | M-5 | 45 | M-3/M-2 | 45/10 | — | — | 46.1 | 44.1/9.8 | — | 3,990 | 1.37 |
| Example 3 | | | | | | | | | | | | |
| Synthesis | B-4 | M-5 | 45 | M-1/M-4 | 45/10 | — | — | 43.7 | 43.6/10.2 | — | 4,130 | 1.45 |
| Example 4 | | | | | | | | | | | | |
| Synthesis | B-5 | M-5/M-6 | 40/10 | M-1 | 50 | — | — | 42.6/8.8 | 48.6 | — | 4,320 | 1.51 |
| Example 5 | | | | | | | | | | | | |
| Synthesis | B-6 | M-5/M-7 | 40/10 | M-1 | 50 | — | — | 41.0/9.8 | 49.2 | — | 3,830 | 1.36 |
| Example 6 | | | | | | | | | | | | |
| Synthesis | B-7 | M-8 | 50 | M-1 | 50 | — | — | 51.5 | 48.5 | — | 4,360 | 1.47 |
| Example 7 | | | | | | | | | | | | |
| Synthesis | B-8 | M-9 | 50 | M-1 | 50 | — | — | 52.2 | 47.8 | — | 4,650 | 1.45 |
| Example 8 | | | | | | | | | | | | |
| Synthesis | B-9 | M-10 | 50 | M-1 | 50 | — | — | 50.6 | 49.4 | — | 4,810 | 1.43 |
| Example 9 | | | | | | | | | | | | |
| Synthesis | B-10 | M-11 | 50 | M-1 | 50 | — | — | 51.9 | 48.1 | — | 4,530 | 1.42 |
| Example 10 | | | | | | | | | | | | |
| Synthesis | B-11 | M-8/M-16 | 40/10 | M-1 | 50 | — | — | 43.4/8.7 | 47.9 | — | 4,660 | 1.45 |
| Example 11 | | | | | | | | | | | | |
| Synthesis | B-12 | M-16 | 50 | M-1 | 50 | — | — | 51.5 | 48.5 | — | 4,720 | 1.51 |
| Example 12 | | | | | | | | | | | | |
| Synthesis | b-1 | — | — | M-1 | 50 | M-14 | 50 | — | 47.5 | 52.5 | 4,360 | 1.48 |
| Example 13 | | | | | | | | | | | | |
| Synthesis | b-2 | — | — | M-1 | 50 | M-15 | 50 | — | 49.3 | 50.7 | 4,610 | 1.47 |
| Example 14 | | | | | | | | | | | | |

### Synthesis of Polymer (C)

### Synthesis Example 15

### Synthesis of Polymer (C-1)

A monomer solution was prepared by dissolving 38.77 g (40 mol %) of compound (M-12) described below and 61.23 g (60 mol %) of compound (M-13) described below in 100 g of 2-butanone, to which 4.97 g of 2,2′-azobis(2-methylpropionitrile) was further charged. A 1,000 mL three-neck flask charged with 100 g of 2-butanone was purged with nitrogen for 30 min. After the nitrogen purge, the reaction vessel was heated to 80° C. while stirring, and the monomer solution prepared beforehand was added dropwise thereto using a dripping funnel over 3 hrs. A time point at which the dropwise addition was started was defined as a polymerization starting time, and a polymerization reaction was carried out for 6 hrs. After completing the polymerization, 150 g of 2-butanone was removed in vacuo from the polymerization solution. After cooling to no higher than 30° C., the solution was charged into a mixed solvent of 760 g of methanol and 40 g of ultra pure water, and the white precipitate was recovered by removing the supernatant liquid. The white precipitate was dissolved in 500 g of propylene glycol monomethyl ether acetate, and concentrated, whereby remaining methanol and remaining ultra pure water were eliminated. Propylene glycol monomethyl ether acetate was added to the obtained concentrate, and thus a copolymer solution having a solid content of 20% was obtained (250 g, yield: 50%). The copolymer had an Mw of 4,210, Mw/Mn of 1.61, and as a result of a ¹³C-NMR analysis, had the content of each of the structure units derived from the compound (M-12) and the compound (M-13) of 40.8:59.2 (mol %). The fluorine content was 9.8% by mass. The copolymer is designated as polymer (C-1).

### <Preparation of Radiation-Sensitive Resin Composition>

Details of each component other than the polymer (B) and the polymer (C), used in the preparation of Examples and Comparative Examples are shown below.

### ((A) Compound)

A-1 to A-5, A-1: compounds represented by the following formulae

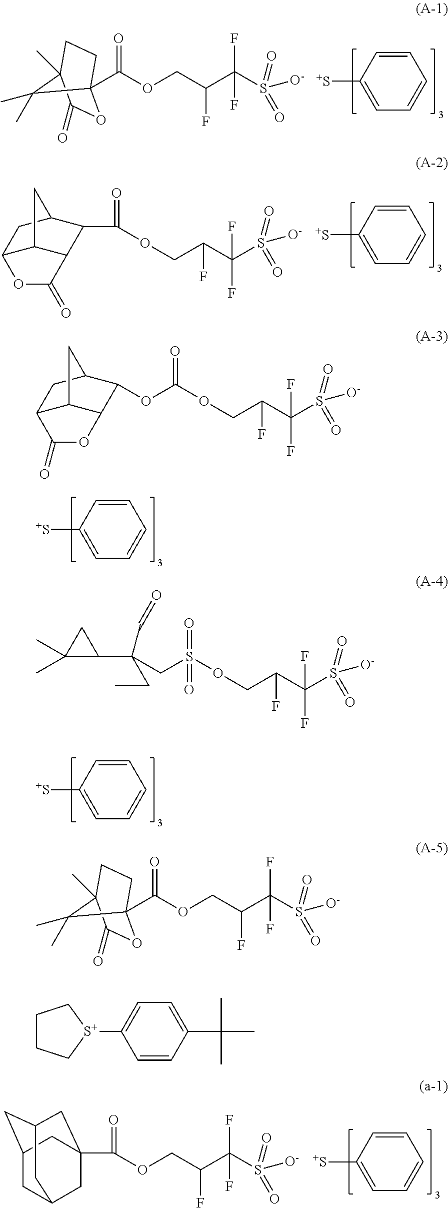

### ((D) Acid Diffusion Control Agent)

D-1 to D-3: compounds represented by the following formulae

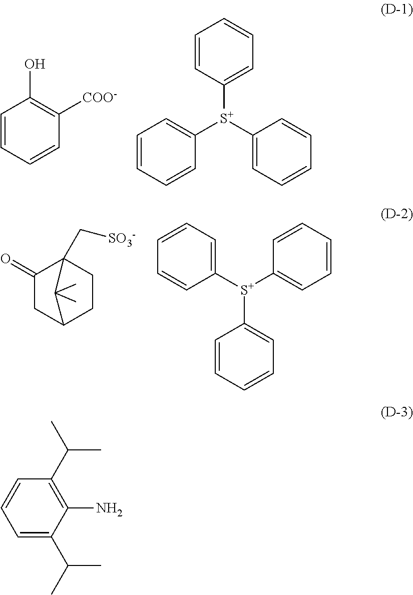

### (Additive ((E) Lactone Compound))

E-1: γ-butyrolactone

### (Solvent)

F-1: propylene glycol monomethyl ether acetate
F-2: cyclohexanone

### (Developer Solution)

MAK: methylamyl ketone
BA: butyl acetate

### Example 1

A radiation-sensitive resin composition was prepared by mixing 10.4 parts by mass of the compound (A-1) as the compound (A), 100 parts by mass of the polymer (B-1) as the polymer (B), 5 parts by mass of the polymer (C-1) as the polymer (C), 7 parts by mass of the compound (D-1) as the acid diffusion control agent (D), 200 parts by mass of the additive (E-1), and 2,600 parts by mass of the solvent (F-1) and 1,100 parts by mass of the solvent (F-2), followed by filtering the resulting mixed solution through a filter having a pore size of 0.2 μm.

### Examples 2 to 19 and Comparative Examples 1 to 3

Each radiation-sensitive resin composition was prepared by a similar operation to Example 1 except that each component of the type and the amount blended shown in Table 2 was used.

### Examples 20 to 21 and Comparative Examples 4 to 5

A radiation-sensitive resin composition was prepared by mixing each component of the type and the amount blended shown in Table 3, 30 parts by mass of the additive (E-1), and 1,930 parts by mass of the solvent (F-1) and 830 parts by mass of the solvent (F-2), followed by filtering the resulting mixed solution through a filter having a pore size of 0.2 μm.

### <Evaluations>

With regard to Examples 1 to 19 and Comparative Examples 1 to 3, a resist pattern was formed in accordance with the above Formation of Positive Type Resist Pattern (P-1), and evaluations of the LWR and MEEF were made. The results are shown in Table 2 together.

With regard to Examples 20 to 21 and Comparative Examples 4 to 5, a resist pattern was formed in accordance with the above Formation of Negative Type Resist Pattern (P-2), and evaluations of the CDU and MEEF were made. The results are shown in Table 3 together.

In addition, evaluation of the development defect inhibitory ability was made on the resist pattern formed in accordance with the above Formation of Positive Type Resist Pattern (P-1), using the radiation-sensitive resin compositions of Example 1 and Comparative Example 1. According to the evaluation of the development defect inhibitory ability, Example was revealed to be favorable, whereas Comparative Example revealed to be unfavorable.

TABLE 2

| | | | | | | | (D) Acid | | | | | |
|---|---|---|---|---|---|---|---|---|---|---|---|---|
| | | | | | | | diffusion | | | | | |
| | (A) Compound | | (B) Polymer | | (C) Polymer | | control agent | | | | | |
| | | amount | | amount | | amount | | amount | | | | |
| | | blended | | blended | | blended | | blended | | | | |
| | | (parts | | (parts | | (parts | | (parts | PB | PEB | LWR | MEEF |
| | type | by mass) | type | by mass) | type | by mass) | type | by mass) | (° C.) | (° C.) | 46 nmLS | 46 nmLS |
| Example 1 | (A-1) | 10.4 | (B-1) | 100 | (C-1) | 5 | (D-1) | 7 | 120 | 100 | 5.7 | 3.4 |
| Example 2 | (A-2) | 10.1 | (B-1) | 100 | (C-1) | 5 | (D-1) | 7 | 120 | 100 | 5.5 | 3.4 |
| Example 3 | (A-3) | 10.4 | (B-1) | 100 | (C-1) | 5 | (D-1) | 7 | 120 | 100 | 5.4 | 3.2 |
| Example 4 | (A-4) | 11.2 | (B-1) | 100 | (C-1) | 5 | (D-1) | 7 | 120 | 100 | 5.5 | 3.1 |
| Example 5 | (A-5) | 9.7 | (B-1) | 100 | (C-1) | 5 | (D-1) | 7 | 120 | 100 | 5.8 | 3.0 |
| Example 6 | (A-1) | 10.4 | (B-1) | 100 | (C-1) | 5 | (D-1) | 7 | 120 | 100 | 5.7 | 3.4 |
| Example 7 | (A-1) | 10.4 | (B-2) | 100 | (C-1) | 5 | (D-1) | 7 | 120 | 100 | 5.5 | 3.6 |
| Example 8 | (A-1) | 10.4 | (B-3) | 100 | (C-1) | 5 | (D-1) | 7 | 120 | 85 | 5.7 | 3.3 |
| Example 9 | (A-1) | 10.4 | (B-4) | 100 | (C-1) | 5 | (D-1) | 7 | 120 | 100 | 5.8 | 3.2 |
| Example 10 | (A-1) | 10.4 | (B-5) | 100 | (C-1) | 5 | (D-1) | 7 | 120 | 100 | 5.5 | 3.6 |
| Example 11 | (A-1) | 10.4 | (B-6) | 100 | (C-1) | 5 | (D-1) | 7 | 120 | 100 | 5.6 | 3.4 |
| Example 12 | (A-1) | 10.4 | (B-7) | 100 | (C-1) | 5 | (D-1) | 7 | 120 | 100 | 5.5 | 3.1 |
| Example 13 | (A-1) | 10.4 | (B-8) | 100 | (C-1) | 5 | (D-1) | 7 | 120 | 100 | 5.8 | 3.1 |
| Example 14 | (A-1) | 10.4 | (B-9) | 100 | (C-1) | 5 | (D-1) | 7 | 120 | 100 | 5.5 | 3.2 |
| Example 15 | (A-1) | 10.4 | (B-10) | 100 | (C-1) | 5 | (D-1) | 7 | 120 | 100 | 5.3 | 3.3 |
| Example 16 | (A-1) | 10.4 | (B-11) | 100 | (C-1) | 5 | (D-1) | 7 | 120 | 100 | 5.7 | 3.1 |
| Example 17 | (A-1) | 10.4 | (B-2) | 100 | (C-1) | 5 | (D-2) | 8.6 | 120 | 100 | 5.7 | 3.3 |
| Example 18 | (A-1) | 10.4 | (B-2) | 100 | (C-1) | 5 | (D-3) | 1.3 | 120 | 100 | 5.9 | 3.1 |
| Example 19 | (A-1) | 10.4 | (B-12) | 100 | (C-1) | 5 | (D-3) | 1.3 | 120 | 100 | 7.0 | 3.4 |
| Comparative | (a-1) | 10.3 | (B-1) | 100 | (C-1) | 5 | (D-1) | 7 | 120 | 100 | 6.2 | 4.0 |
| Example 1 | | | | | | | | | | | | |
| Comparative | (A-1) | 10.4 | (b-1) | 100 | (C-1) | 5 | (D-3) | 1.3 | 120 | 110 | 8.9 | 3.6 |
| Example 2 | | | | | | | | | | | | |
| Comparative | (A-1) | 10.4 | (b-2) | 100 | (C-1) | 5 | (D-3) | 1.3 | 120 | 110 | 9.1 | 3.4 |
| Example 3 | | | | | | | | | | | | |

TABLE 3

| | | | | | | | (D) acid diffusion | | | | | | |
|---|---|---|---|---|---|---|---|---|---|---|---|---|---|
| | (A) compound | | (B) polymer | | (C) polymer | | control agent | | | | | | |
| | | amount | | amount | | amount | | amount | | | | | |
| | | blended | | blended | | blended | | blended | | | | CDU | MEEF |
| | | (parts | | (parts | | (parts | | (parts | PB | PEB | developer | 55 nm | 55 nm |
| | type | by mass) | type | by mass) | type | by mass) | type | by mass) | (° C.) | (° C.) | solution | Hole | Hole |
| Example 20 | (A-1) | 10.4 | (B-1) | 100 | (C-1) | 3 | (D-2) | 2.1 | 120 | 100 | MAK | 2.5 | 3.4 |
| Example 21 | (A-1) | 10.4 | (B-1) | 100 | (C-1) | 3 | (D-2) | 2.1 | 120 | 100 | BA | 3.0 | 3.2 |
| Comparative | (a-1) | 10.1 | (B-1) | 100 | (C-1) | 3 | (D-2) | 2.1 | 120 | 100 | MAK | 2.6 | 3.7 |
| Example 4 | | | | | | | | | | | | | |
| Comparative | (a-1) | 10.1 | (B-1) | 100 | (C-1) | 3 | (D-2) | 2.1 | 120 | 100 | BA | 3.1 | 3.5 |
| Example 5 | | | | | | | | | | | | | |

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a compound represented by a following formula (1):
R¹—R²—X—R³—CHF—CF₂—SO₃⁻M⁺ (1)
wherein, in the formula (1), R¹ represents a monovalent cyclic organic group having a cyclic ester structure or a cyclic ketone structure; R² represents a single bond or —CH₂—; X is —O—*, —COO—*, —O—CO—O—* or —SO2-O—*, wherein * denotes a binding site to R³; R³ represents a bivalent chain hydrocarbon group having 1 to 5 carbon atoms; and
M⁺ is a monovalent cation; and
a base polymer having a structural unit derived from (meth)acrylate that includes a lactone skeleton, a structural unit derived from (meth)acrylate that includes a cyclic carbonate skeleton, a structural unit derived from (meth)acrylate that includes a sultone skeleton, a structural unit derived from (meth)acrylate that includes a polar group, or a combination thereof.

2. The radiation-sensitive resin composition according to claim 1, further comprising a fluorine-containing polymer.

3. The radiation-sensitive resin composition according to claim 1, wherein R¹ in the above formula (1) represents a group represented by a following formula (a1), a group represented by a following formula (a2), or a group represented by a following formula (a3), 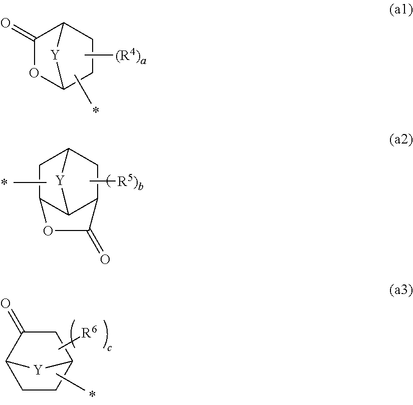
wherein, in the formulae (a1) to (a3), each Y is independently —CH₂—, —C(CH₃)₂— or —O—; R⁴, R⁵ and R⁶ each independently represent an alkyl group having 1 to 5 carbon atoms, a cyano group or a hydroxyl group; a, b and c are each independently an integer of 0 to 5; and * denotes a binding site to R².

4. The radiation-sensitive resin composition according to claim 1, wherein M⁺ in the formula (1) is a sulfonium cation or an iodonium cation.

5. The radiation-sensitive resin composition according to claim 4, wherein M⁺ in the formula (1) is represented by a following formula (b): 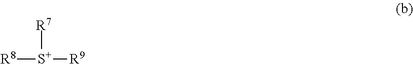
wherein, in the formula (b),
R⁷, R⁸ and R⁹ each independently represent a substituted or unsubstituted linear or branched alkyl group, alkenyl group or oxoalkyl group having 1 to 10 carbon atoms, or a substituted or unsubstituted aryl group, aralkyl group or aryloxoalkyl group having 6 to 18 carbon atoms, or
two or more of R⁷, R⁸ and R⁹ taken together represent a ring together with the sulfur atom present in the formula (b), and each of R⁷, R⁸ and R⁹ other than the two or more of R⁷, R⁸ and R⁹ represents a substituted or unsubstituted linear or branched alkyl group, alkenyl group or oxoalkyl group having 1 to 10 carbon atoms, or a substituted or unsubstituted aryl group, aralkyl group or aryloxoalkyl group having 6 to 18 carbon atoms.

6. The radiation-sensitive resin composition according to claim 1, wherein the base polymer further has a structural unit represented by a following formula (2): 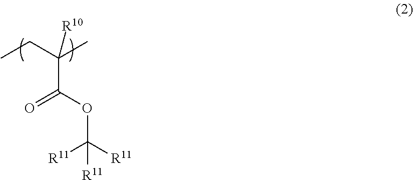
wherein, in the formula (2), R¹⁰ represents a hydrogen atom or a methyl group; each R¹¹ independently represents a linear or branched alkyl group having 1 to 4 carbon atoms, or alicyclic hydrocarbon group having 4 to 20 carbon atoms, or two of R¹¹s taken together represent an alicyclic hydrocarbon group having 4 to 20 carbon atoms together with the carbon atom to which the two of R¹¹s bond and R¹¹ other than the two of R¹¹s represents a linear or branched alkyl group having 1 to 4 carbon atoms, or alicyclic hydrocarbon group having 4 to 20 carbon atoms.

7. The radiation-sensitive resin composition according to claim 1, wherein the base polymer has the structural unit derived from (meth)acrylate that includes a polar group, and the polar group is a hydroxyl group.
